(19) United States
(12) Patent Application Publication
(10) Pub. No.: US 2025/0070074 A1
(43) Pub. Date: Feb. 27, 2025

(54) SEMICONDUCTOR DEVICE

(71) Applicant: FUJI ELECTRIC CO., LTD., Kawasaki-shi (JP)

(72) Inventor: Hiroaki HOKAZONO, Hachioji-city (JP)

(73) Assignee: FUJI ELECTRIC CO., LTD., Kawasaki-shi (JP)

(21) Appl. No.: 18/756,361

(22) Filed: Jun. 27, 2024

(30) Foreign Application Priority Data
Aug. 23, 2023 (JP) 2023-135332

(51) Int. Cl. H01L 23/00; H01L 23/057; H01L 23/31; H01L 23/36; H01L 23/538; H01L 25/065

(52) U.S. Cl. CPC H01L 24/40; H01L 24/32; H01L 24/48; H01L 24/73; H01L 23/057; H01L 23/3107; H01L 23/36; H01L 23/5383; H01L 25/0655; H01L 2224/32225; H01L 2224/4005; H01L 2224/40225; H01L 2224/40475; H01L 2224/48227; H01L 2224/73263

(57) ABSTRACT

A semiconductor device, including an electrically conductive portion, and a terminal. The terminal includes a bonding portion that is of a flat plate shape and has: a rear surface bonded to the electrically conductive portion, and a front surface having an indentation formed thereon. The front surface has two opposite sides that are respectively a bonding front-end side and a bonding rear-end side. The indentation has two opposite sides that are respectively an indentation front-end side and an indentation rear-end side. The indentation front-end side is flush with the bonding front-end side. A length of the indentation rear-end side is shorter than a length of the bonding rear-end side.

### CROSS-REFERENCE TO RELATED APPLICATION

This application is based upon and claims the benefit of priority of the prior Japanese Patent Application No. 2023-135332, filed on Aug. 23, 2023, the entire contents of which are incorporated herein by reference.

### BACKGROUND OF THE INVENTION

### 1. Field of the Invention

The embodiments discussed herein relate to a semiconductor device.

### 2. Background of the Related Art

In a semiconductor device, a member is bonded to another member by ultrasonic bonding (for example, see Japanese Laid-open Patent Publication No. 2010-212645 and Japanese Laid-open Patent Publication No. 2013-226580). In addition, a wire is bonded to a member by ultrasonic bonding (for example, see Japanese Laid-open Patent Publication No. 2000-299347).

### SUMMARY OF THE INVENTION

According to one aspect, there is provided a semiconductor device, including: an electrically conductive portion; and a terminal, wherein the terminal includes a bonding portion that is of a flat plate shape, wherein the bonding portion has: a rear surface bonded to the electrically conductive portion, and a front surface having an indentation formed thereon, wherein the front surface has two opposite sides that are respectively a bonding front-end side and a bonding rear-end side, wherein the indentation has two opposite sides that are respectively an indentation front-end side and an indentation rear-end side, wherein the indentation front-end side is flush with the bonding front-end side, and wherein a length of the indentation rear-end side is shorter than a length of the bonding rear-end side.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a plan view of a semiconductor unit included in the semiconductor device according to the first embodiment;

FIG. 4 is a first sectional view of the semiconductor unit included in the semiconductor device according to the first embodiment;

FIG. 5 is a second sectional view of the semiconductor unit included in the semiconductor device according to the first embodiment;

FIG. 6 is a flowchart of a manufacturing method of the semiconductor device according to the first embodiment;

FIG. 7 illustrates an assembly step included in the manufacturing method of the semiconductor device according to the first embodiment;

FIG. 8 is an enlarged plan view of a bonding portion after the assembly step included in the manufacturing method of the semiconductor device according to the first embodiment;

FIG. 9 is an enlarged sectional view of the bonding portion after the assembly step included in the manufacturing method of the semiconductor device according to the first embodiment;

FIG. 10 is a side view of a bonding tool used in a wiring step included in the manufacturing method of the semiconductor device according to the first embodiment;

FIG. 11 is a plan view of a bonding tip portion of the bonding tool used in the wiring step included in the manufacturing method of the semiconductor device according to the first embodiment;

FIGS. 12A and 12B are first sectional views of the bonding tip portion of the bonding tool used in the wiring step included in the manufacturing method of the semiconductor device according to the first embodiment;

FIGS. 13A and 13B are second sectional views of the bonding tip portion of the bonding tool used in the wiring step included in the manufacturing method of the semiconductor device according to the first embodiment;

FIG. 14 is a plan view illustrating the wiring step (at bonding) included in the manufacturing method of the semiconductor device according to the first embodiment;

FIG. 15 is a sectional view illustrating the wiring step (at bonding) included in the manufacturing method of the semiconductor device according to the first embodiment;

FIG. 16 is a plan view of a main part, illustrating the wiring step (at bonding) included in the manufacturing method of the semiconductor device according to the first embodiment;

FIG. 17 is a sectional view of the main part, illustrating the wiring step (at bonding) included in the manufacturing method of the semiconductor device according to the first embodiment;

FIG. 18 is a plan view of the main part, illustrating the wiring step (after bonding) included in the manufacturing method of the semiconductor device according to the first embodiment;

FIG. 19 is a sectional view of the main part, illustrating the wiring step (after bonding) included in the manufacturing method of the semiconductor device according to the first embodiment;

FIG. 20 is a plan view of a main part, illustrating a wiring step (at bonding) included in a manufacturing method of a semiconductor device according to a reference example;

FIG. 21 is a sectional view of the main part, illustrating the wiring step (at bonding) included in the manufacturing method of the semiconductor device according to the reference example;

FIG. 22 illustrates a side surface of the main part, illustrating the wiring step (after bonding) included in the manufacturing method of the semiconductor device according to the reference example;

FIG. 23 is a plan view of a main part, illustrating a wiring step (at bonding) included in a manufacturing method of a semiconductor device according to a second embodiment;

FIG. 24 is a plan view of the main part, illustrating the wiring step (after bonding) included in the manufacturing method of the semiconductor device according to the second embodiment;

FIG. 25 is a plan view illustrating a wiring step (at bonding) included in a manufacturing method of a semiconductor device according to a third embodiment; and

FIG. 26 is a plan view of a main part, illustrating the wiring step (after bonding) included in the manufacturing method of the semiconductor device according to the third embodiment.

### DETAILED DESCRIPTION OF THE INVENTION

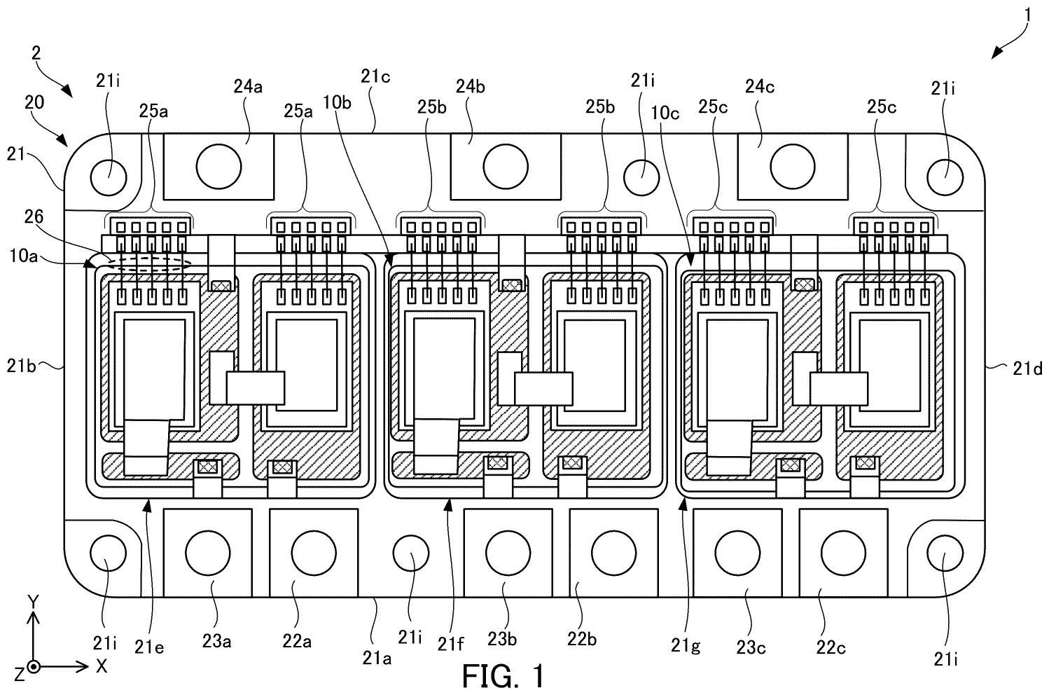

Hereinafter, embodiments will be described with reference to the accompanying drawings. In the following description, regarding a semiconductor device 1 in FIG. 1, terms “front surface” and “top surface” each express an X-Y surface facing upward (the Z direction). Likewise, regarding the semiconductor device 1 in FIG. 1, a term “up” expresses the upper direction (the +Z direction). Regarding the semiconductor device 1 in FIG. 1, terms “rear surface” and “bottom surface” each express an X-Y surface facing downward (the −Z direction). Likewise, regarding the semiconductor device 1 in FIG. 1, a term “down” expresses the lower direction (the −Z direction). In all the other drawings, the above terms also mean their respective directions as appropriate. Regarding the semiconductor device 1 in FIG. 1, terms “higher level” and “upper level” express an upper location (in the +Z direction). Likewise, regarding the semiconductor device 1 in FIG. 1, terms “low level” and “lower level” express a lower location (in the −Z direction). The terms “front surface”, “top surface”, “up”, “rear surface”, “bottom surface”, “down”, and “side surface” are simply used as convenient expressions to determine relative positional relationships and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in material represents 80 vol % or more of the material, this component will be referred to as “main component” of the material. In addition, an expression “approximately the same” may be used when an error between two elements is within in ±10%. In addition, even when two elements are not exactly perpendicular, orthogonal, or parallel to each other, the two elements may be described as being “perpendicular”, “orthogonal”, or “parallel” to each other if the error is within ±10°.

### First Embodiment

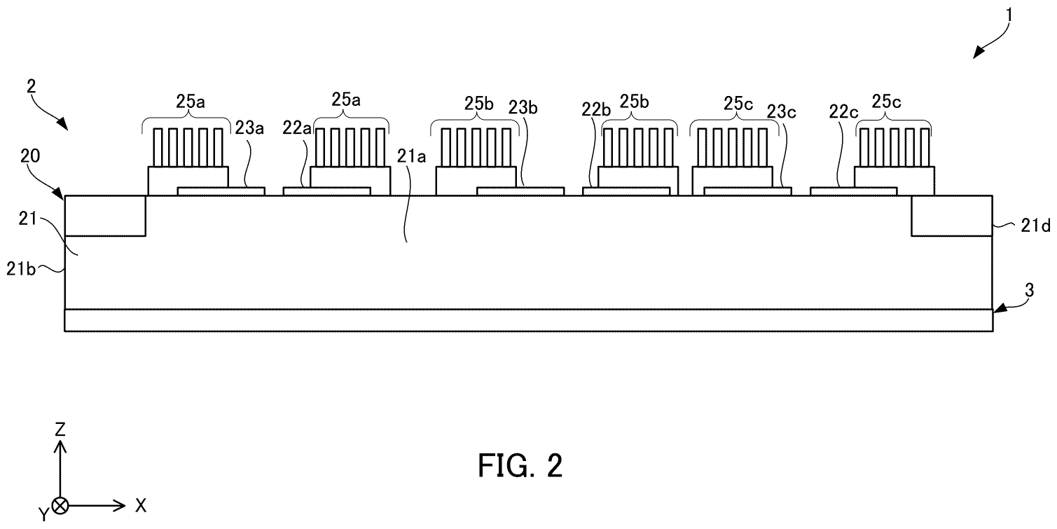

A semiconductor device 1 according to a first embodiment will be described with reference to FIGS. 1 and 2. FIG. 1 is a plan view of the semiconductor device according to the first embodiment, and FIG. 2 is a side view of the semiconductor device according to the first embodiment. FIG. 2 is a side view in which a side portion of the semiconductor device 1 in FIG. 1 is seen in the +Y direction. The side portion is parallel to the X-Z plane.

The semiconductor device 1 includes a semiconductor module 2 and a heat dissipation plate 3. The semiconductor module 2 includes semiconductor units 10a, 10b, and 10c and a case 20 storing the semiconductor units 10a, 10b, and 10c. The semiconductor units 10a, 10b, and 10c stored in the case 20 are sealed by sealing material (not illustrated). Each of the semiconductor units 10a, 10b, and 10c has the same construction. When the semiconductor units 10a, 10b, and 10c are not distinguished from each other, any one of the semiconductor units 10a, 10b, and 10c will be described as a semiconductor unit 10. The semiconductor units 10 will be described in detail below.

The case 20 included in the semiconductor module 2 includes an outer frame 21, first connection terminals 22a, 22b, and 22c, second connection terminals 23a, 23b, and 23c, a U-phase output terminal 24a, a V-phase output terminal 24b, a W-phase output terminal 24c, and control terminals 25a, 25b, and 25c.

The outer frame has 21 an approximately rectangular shape in plan view, and four sides of the outer frame 21 constitute outer walls 21a, 21b, 21c, and 21d. The outer walls 21a and 21c constitute the long sides of the outer frame 21, and the outer walls 21b and 21d constitute the short sides of the outer frame 21. In addition, the outer frame 21 has corner portions, each of which is formed by connection of two of the outer walls 21a, 21b, 21c, and 21d. These corner portions may be right-angled corner portions or rounded corner portions as illustrated in FIG. 1. Fastening holes 21i, each of which extends through the outer frame 21, are formed in their respective corner portions, and on the front surface near the outer walls 21a and 21c, of the front surface of the outer frame 21. Each of the fastening holes 21i in the corner portions, and on the front surface near the outer walls 21a and 21c, of the outer frame 21 may be formed in a surface lower than the front surface of the outer frame 21.

In the front surface of the outer frame 21, unit storage portions 21e, 21f, and 21g are defined along the outer walls 21a and 21c. Each of these unit storage portions 21e, 21f, and 21g has a rectangular shape in plan view. The semiconductor units 10a, 10b, and 10c are stored in the unit storage portions 21e, 21f, and 21g, respectively. The outer frame 21 is attached to the front surface of the heat dissipation plate 3 on which the semiconductor units 10a, 10b, and 10c have been arranged in the X direction. After the outer frame 21 is attached to the heat dissipation plate 3, the unit storage portions 21e, 21f, and 21g of the outer frame 21 enclose (store) their respective semiconductor units 10a, 10b, and 10c arranged on the heat dissipation plate 3.

The outer frame 21 has the first connection terminals 22a, 22b, and 22c and the second connection terminals 23a, 23b, and 23c on the front surface near the outer wall 21a in plan view. The first and second connection terminals 22a and 23a, 22b and 23b, and 22c and 23c are formed at the unit storage portions 21e, 21f, and 21g, respectively. The first connection terminals 22a, 22b, and 22c and the second connection terminals 23a, 23b, and 23c each have one end that appears on the front surface near the outer wall 21a. In addition, the first connection terminals 22a, 22b, and 22c and the second connection terminals 23a, 23b, and 23c each have the other end that appears inside a corresponding one of the unit storage portions 21e, 21f, and 21g and that is electrically connected to a corresponding one of the semiconductor units 10a, 10b, and 10c.

The U-phase output terminal 24a, the V-phase output terminal 24b, and the W-phase output terminal 24c are formed on the front surface near the outer wall 21c. The U-phase output terminal 24a, the V-phase output terminal 24b, and the W-phase output terminal 24c are formed in the unit storage portions 21e, 21f, and 21g, respectively. The U-phase output terminal 24a, the V-phase output terminal 24b, and the W-phase output terminal 24c each have one end that appears on the front surface near the outer wall 21c. The U-phase output terminal 24a, the V-phase output terminal 24b, and the W-phase output terminal 24c each have the other end that appears in a corresponding one of unit storage portions 21e, 21f, and 21g and that is electrically connected to a corresponding one of the semiconductor units 10a, 10b, and 10c.

In addition, the outer frame 21 has openings for the first connection terminals 22a, 22b, and 22c and the second connection terminals 23a, 23b, and 23c, and nuts are stored under these openings such that the nuts face their respective openings. Similarly, the outer frame 21 has openings for the U-phase output terminal 24a, the V-phase output terminal 24b, and the W-phase output terminal 24c, and nuts are stored under these openings such that the nuts face their respective openings.

In addition, the outer frame 21 includes the control terminals 25a, 25b, and 25c. The control terminals 25a are arranged on the front surface of the outer frame 21 near the +Y direction side of the unit storage portion 21e in plan view (the side being located in the direction of the outer wall 21c). In the same way, the control terminals 25b and 25c are also arranged on the front surface of the outer frame 21 near the +Y direction side of the unit storage portions 21f and 21g in plan view (the side being located in the direction of the outer wall 21c). The control terminals 25a are divided into two groups, and the same applies to the control terminals 25b and 25c. Each of the control terminals 25a, 25b, and 25c is formed in the shape of the letter “J” (or “U”), and has one end extending vertically upward (in the +Z direction) from the front surface near the outer wall 21c of the outer frame 21. The control terminals 25a, 25b, and 25c each have the other end that faces in the −Y direction from the +Y direction side of a corresponding one of the unit storage portions 21e, 21f, and 21g, the side being located in the direction of the outer wall 21c, and that appears in the corresponding one of the unit storage portions 21e, 21f, and 21g.

The outer frame 21 includes the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c, each of which is a specific example of a terminal. The outer frame 21 and these components are integrally formed by injection molding that uses thermoplastic resin. In this way, the case 20 is constructed. Examples of the thermoplastic resin include polyphenylene sulfide resin, polybutylene terephthalate resin, polybutylene succinate resin, polyamide resin, and acrylonitrile butadiene styrene resin.

In addition, the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c are each made of a metal material having an excellent electrical conductivity. For example, this metal material is copper, aluminum, or an alloy containing at least one of these kinds of elements as its main component. The surface of each of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c may be plated. The material used for this plating is, for example, nickel, a nickel-phosphorus alloy, or a nickel-boron alloy. The structure of an end of the second connection terminal 23b will be described in detail below. The first connection terminals 22a, 22b, and 22c, the second connection terminals 23a and 23c, the U-phase output terminal 24a, the V-phase output terminal 24b, the W-phase output terminal 24c, and the control terminals 25a, 25b, and 25c also have a structure equivalent to that of the end of the second connection terminal 23b.

Sealing material is injected into the unit storage portions 21e, 21f, and 21g of the outer frame 21, so as to seal the semiconductor units 10 inside the unit storage portions 21e, 21f, and 21g. The sealing material seals the other end of each of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c in the unit storage portions 21e, 21f, and 21g. The sealing material may be thermosetting resin. The thermosetting resin is, for example, epoxy resin, phenol resin, maleimide resin, or polyester resin. Preferably, the thermosetting resin is epoxy resin. In addition, filler may be added to the sealing material. The filler is an insulating ceramic material having a high thermal conductivity.

The heat dissipation plate 3 has a rectangular flat plate shape in plan view. The heat dissipation plate 3 has rounded corners in plan view. In addition, the heat dissipation plate 3 has insertion holes at locations corresponding to the fastening holes 21i in plan view. The semiconductor module 2 is disposed on the front surface of the heat dissipation plate 3 via adhesive, which will be described below. A cooling device may be attached to an area of the rear surface of the heat dissipation plate 3, the area corresponding to the area where the semiconductor module 2 is disposed. In this case, a pump is connected to this cooling device, and refrigerant is circulated by the pump. With this pump, the refrigerant flows into the cooling device, and the refrigerant circulates inside the cooling device. In this circulation process, the refrigerant receives the heat from the semiconductor module 2, and the semiconductor module 2 is consequently cooled. The refrigerant, which has received the heat, is discharged to the outside of the cooling device. The refrigerant is circulated inside the cooling device by the pump in this way. Alternatively, only a plurality of heat dissipation fins may be formed on the rear surface of the heat dissipation plate 3. In this case, the semiconductor module 2 is cooled by air cooling.

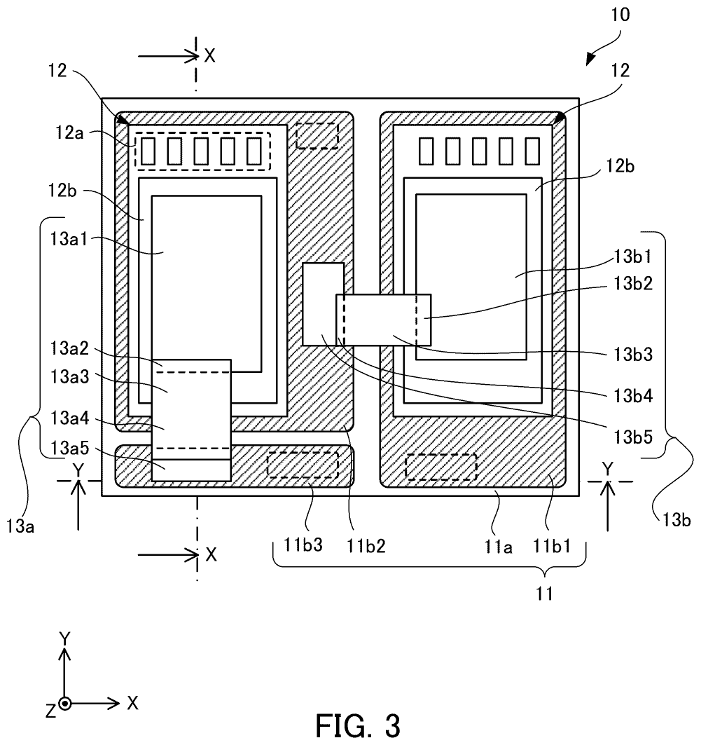

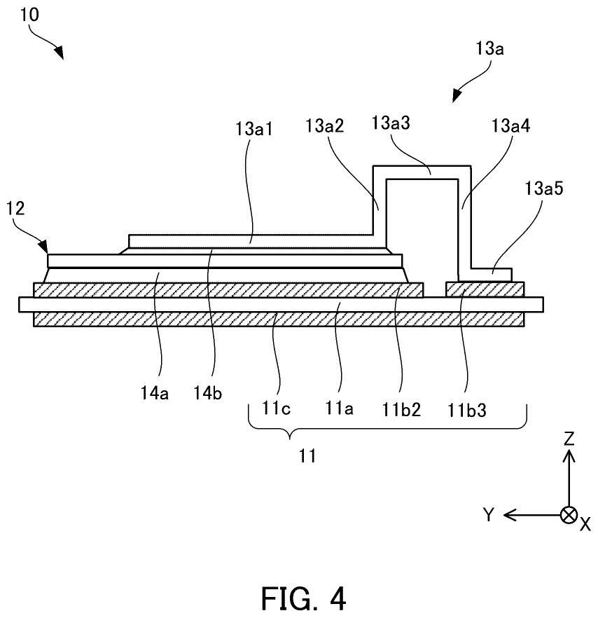

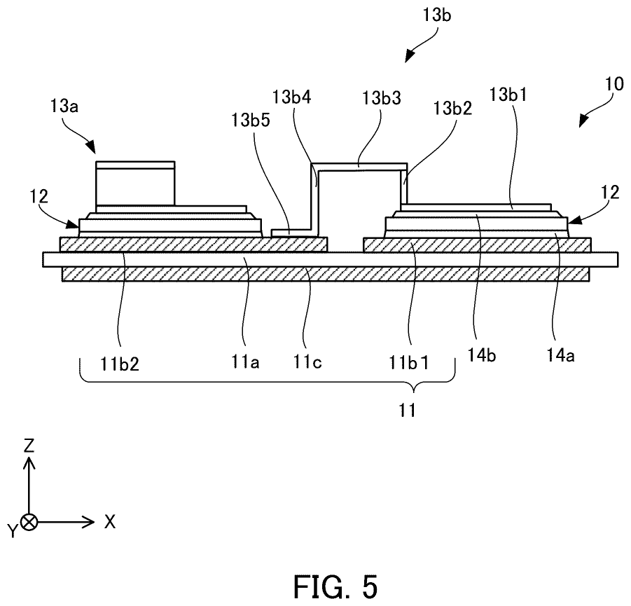

Next, the semiconductor units 10a, 10b, and 10c (semiconductor units 10) will be described with reference to FIGS. 3 to 5. FIG. 3 is a plan view of a semiconductor unit included in the semiconductor device according to the first embodiment. FIG. 4 is a first sectional view of the semiconductor unit included in the semiconductor device according to the first embodiment. FIG. 5 is a second sectional view of the semiconductor unit included in the semiconductor device according to the first embodiment. Specifically, FIG. 4 is a sectional view taken along a dash-dotted line X-X in FIG. 3, and FIG. 5 is a sectional view taken along a dash-dotted line Y-Y in FIG. 3.

The individual semiconductor unit 10 includes an insulated circuit board 11, two semiconductor chips 12, and lead frames 13a and 13b. The semiconductor chips 12 are each bonded to the insulated circuit board 11 via a bonding material 14a. The lead frames 13a and 13b are each bonded to a main electrode 12b on the front surface of a corresponding one of the semiconductor chips 12 via a bonding material 14b. The lead frames 13a and 13b may be bonded to the insulated circuit board 11 by ultrasonic bonding, instead of using the bonding material 14b.

The insulated circuit board 11 includes an insulating plate 11a, wiring plates 11b1, 11b2, and 11b3, and a metal plate 11c. The insulating plate 11a and the metal plate 11c each have a rectangular shape in plan view.

The insulating plate 11a and the metal plate 11c may have rounded or chamfered corners. The metal plate 11c is smaller than the insulating plate 11a and is formed inside the insulating plate 11a in plan view.

The insulating plate 11a is made of an insulating material having an excellent thermal conductivity. The insulating plate 11a is made of a ceramic material, examples of which include aluminum oxide, aluminum nitride, and silicon nitride.

The wiring plates 11b1, 11b2, and 11b3 are each an example of an electrically conductive portion, and are each formed on the front surface of the insulating plate 11a. The wiring plates 11b1, 11b2, and 11b3 are each made of a metal material having an excellent electrical conductivity. For example, this metal material is copper, aluminum, or an alloy containing at least one of these kinds of elements as its main component. For example, the wiring plates 11b1, 11b2, and 11b3 each have a thickness between 0.1 mm and 2.0 mm, inclusive. The surface of each of the wiring plates 11b1, 11b2, and 11b3 may be plated to improve its corrosion resistance. The material used for this plating is, for example, nickel, a nickel-phosphorus alloy, or a nickel-boron alloy.

The wiring plate 11b1 is formed on approximately one half of the area of the front surface of the insulating plate 11a, the area occupied by the wiring plate 11b1 being located in the +X direction side of the insulating plate 11a. The area occupied by the wiring plate 11b1 ranges from the −Y direction side to the +Y direction side of the front surface of the insulating plate 11a. The wiring plate 11b1 has an area surrounded by a dashed line, and an end of a corresponding one of the first connection terminals 22a, 22b, and 22c is bonded to this area. Ultrasonic bonding is used for this bonding.

The wiring plate 11b2 occupies approximately the other half of the area of the front surface of the insulating plate 11a, the area occupied by the wiring plate 11b2 being located in the −X direction side of the insulating plate 11a. The wiring plate 11b2 ranges from the +Y direction side of the front surface of the insulating plate 11a to a location little before the −Y direction side of the front surface of the insulating plate 11a. The wiring plate 11b2 has an area surrounded by a dashed line, and an end of a corresponding one of the U-phase output terminal 24a, the V-phase output terminal 24b, and the W-phase output terminal 24c is bonded to this area. Ultrasonic bonding is used for this bonding.

The wiring plate 11b3 occupies an area surrounded by the wiring plates 11b1 and 11b2 on the front surface of the insulating plate 11a. The wiring plate 11b3 has an area surrounded by a dashed line, and an end of a corresponding one of the second connection terminals 23a, 23b, and 23c is bonded to this area. Ultrasonic bonding is used for this bonding.

These wiring plates 11b1, 11b2, and 11b3 are formed on the front surface of the insulating plate 11a as follows. First, a metal layer is formed on the front surface of the insulating plate 11a. Next, for example, by etching this metal layer, the wiring plates 11b1, 11b2, and 11b3, each of which has a predetermined shape, are obtained. Alternatively, the wiring plates 11b1, 11b2, and 11b3, which have been cut out of a metal layer in advance, may be bonded to the front surface of the insulating plate 11a by a brazing material such as silver. These wiring plates 11b1, 11b2, and 11b3 are only examples. The number, shape, size, or location of the wiring plates 11b1, 11b2, and 11b3 may be suitably determined, as appropriate.

The metal plate 11c is formed on the rear surface of the insulating plate 11a. The metal plate 11c has a rectangular shape. The area of the metal plate 11c is smaller than that of the insulating plate 11a and is larger than the area where the wiring plates 11b1, 11b2, and 11b3 are formed in plan view. The metal plate 11c may have rounded or chamfered corners. The metal plate 11c is formed on the entire area of the insulating plate 11a, excepting the periphery of the insulating plate 11a. The metal plate 11c is made of a material containing a metal material having an excellent thermal conductivity as its main component. For example, the metal material is copper, aluminum, or an alloy containing at least one of these kinds of elements.

For example, a direct copper bonding (DCB) board or an active metal brazed (AMB) board may be used as the insulated circuit board 11 having the above construction. The insulated circuit board 11 may be attached to the front surface of the heat dissipation plate 3 via bonding material (not illustrated). The heat generated by the semiconductor chips 12 is transferred to the heat dissipation plate 3 via the wiring plates 11b1 and 11b2, the insulating plate 11a, and the metal plate 11c, and is consequently dissipated.

The bonding materials 14a and 14b are solder. Lead-free solder is used as the solder. The main component of the lead-free solder is, for example, an alloy containing at least two of tin, silver, copper, zinc, antimony, indium, and bismuth. The solder may also contain additive, which is, for example, nickel, germanium, cobalt, or silicon. Because solder containing such additive as described above has improved wettability, luster, and bonding strength, the reliability is improved.

In addition, a brazing material or a thermal interface material may be used as the bonding material (not illustrated) for bonding the individual semiconductor unit 10 and the heat dissipation plate 3. For example, the main component of the brazing material is one of a tin alloy, an aluminum alloy, a titanium alloy, a magnesium alloy, a zirconium alloy, and a silicon alloy. For example, the thermal interface material is an adhesive material, such as an elastomer sheet, room temperature vulcanization (RTV) rubber, gel, or phase change material or is silicone to which a ceramic material has been added. By attaching the individual semiconductor unit 10 to the heat dissipation plate 3 via the brazing material or the thermal interface material as described above, the heat dissipation of the individual semiconductor unit 10 is improved.

The individual semiconductor chip 12 includes a power device element made of silicon. The power device element is a reverse-conducting (RC)-insulated gate bipolar transistor (IGBT). The RC-IGBT is a semiconductor element constituted by forming an IGBT functioning as a switching element and a free-wheeling diode (FWD) functioning as a diode element, which are connected in anti-parallel, on one chip. The semiconductor chip 12 includes, on its front surface, control electrodes 12a (gate electrodes) and an output electrode (an emitter electrode) functioning as the main electrode 12b. The semiconductor chip 12 includes, on its rear surface, an input electrode (a collector electrode) functioning as a main electrode. The control electrodes 12a are formed along one side of the front surface of the semiconductor chip 12. The output electrode is formed in a center portion of the front surface of the semiconductor chip 12.

Alternatively, the semiconductor chip 12 may be a power metal-oxide-semiconductor field-effect transistor (MOSFET) made of silicon carbide. A power MOSFET whose body diode functions as an FWD may be used. This semiconductor chip 12 includes an input electrode (a drain electrode) as a main electrode on its rear surface, and includes an output electrode (a source electrode) functioning as a main electrode 12b and control electrodes 12a (gate electrodes) on its front surface, for example.

Alternatively, the semiconductor chip 12 may include a set of a switching element and a diode element, each of which is made of silicon, instead of an RC-IGBT or a power MOSFET. The switching element is, for example, an IGBT or a power MOSFET. In this case, the semiconductor chip 12 includes, for example, an input electrode (a drain electrode or a collector electrode) as a main electrode on its rear surface, and includes control electrodes 12a (gate electrodes) and an output electrode (a source electrode or an emitter electrode) as a main electrode 12b on its front surface. For example, the diode element uses a Schottky barrier diode (SBD) or a P-intrinsic-N (PiN) diode as an FWD. The semiconductor chip 12 as described above includes an output electrode (a cathode electrode) as a main electrode on its rear surface and an input electrode (an anode electrode) as a main electrode on its front surface.

The lead frames 13a and 13b electrically connect and wire the semiconductor chips 12 and the wiring plates 11b1, 11b2, and 11b3. The individual semiconductor unit 10 may be a device that constitutes an inverter circuit of a single phase. The lead frame 13a directly connects the main electrode 12b of the semiconductor chip 12 (on the wiring plate 11b2) and the wiring plate 11b3. The lead frame 13b directly connects the main electrode 12b of the semiconductor chip 12 (on the wiring plate 11b1) and the wiring plate 11b2.

As illustrated in FIGS. 3 to 5, the lead frame 13a integrally includes a main electrode bonding portion 13a1, a first vertical linkage portion 13a2, a horizontal linkage portion 13a3, a second vertical linkage portion 13a4, and a wiring bonding portion 13a5. The lead frame 13b integrally includes a main electrode bonding portion 13b1, a first vertical linkage portion 13b2, a horizontal linkage portion 13b3, a second vertical linkage portion 13b4, and a wiring bonding portion 13b5. The lead frames 13a and 13b generally have the same thickness and have a flat plate shape. The above portions may be constructed by bending the lead frames 13a and 13b. The lead frames 13a and 13b are each made of a metal material having an excellent electrical conductivity. For example, this metal material is copper, aluminum, or an alloy containing at least one of these kinds of elements as its main component. The surface of each of the lead frames 13a and 13b may be plated to improve its corrosion resistance. The material used for this plating is, for example, nickel, a nickel-phosphorus alloy, or a nickel-boron alloy.

The main electrode bonding portions 13al and 13b1 each have a flat plate shape. The main electrode bonding portions 13a1 and 13b1 are bonded to the main electrodes 12b of their respective semiconductor chips 12 (on the wiring plates 11b2 and 11b1) via the bonding material 14b. The wiring bonding portions 13a5 and 13b5 may be bonded to the wiring plates 11b3 and 11b2, respectively, via the above-described bonding material or by ultrasonic bonding.

The first vertical linkage portion 13a2, the horizontal linkage portion 13a3, the second vertical linkage portion 13a4, and the wiring bonding portion 13a5 of the lead frame 13a have the same width. This width is a length in directions (the ±X directions) perpendicular to the wiring directions (the +Y directions) of the lead frame 13a. The first vertical linkage portion 13b2, the horizontal linkage portion 13b3, and the second vertical linkage portion 13b4 of the lead frame 13b have the same width. This width is a length in directions (the +Y directions) perpendicular to the wiring directions (the +X directions) of the lead frame 13b.

In addition, the control electrodes 12a of the semiconductor chips 12 of the semiconductor units 10a, 10b, and 10c stored in the unit storage portions 21e, 21f, and 21g of the case 20 are mechanically and electrically connected to the other ends of the control terminals 25a, 25b, and 25c by wires 26. The main component of each of these wires 26 is a material having an excellent electrical conductivity. The material is, for example, gold, copper, aluminum, or an alloy containing at least one of these kinds of elements. Preferably, the main component of the individual wire 26 may be an aluminum alloy containing a minute amount of silicon. For example, the individual wire 26 has a diameter between 100 μm and 400 μm, inclusive.

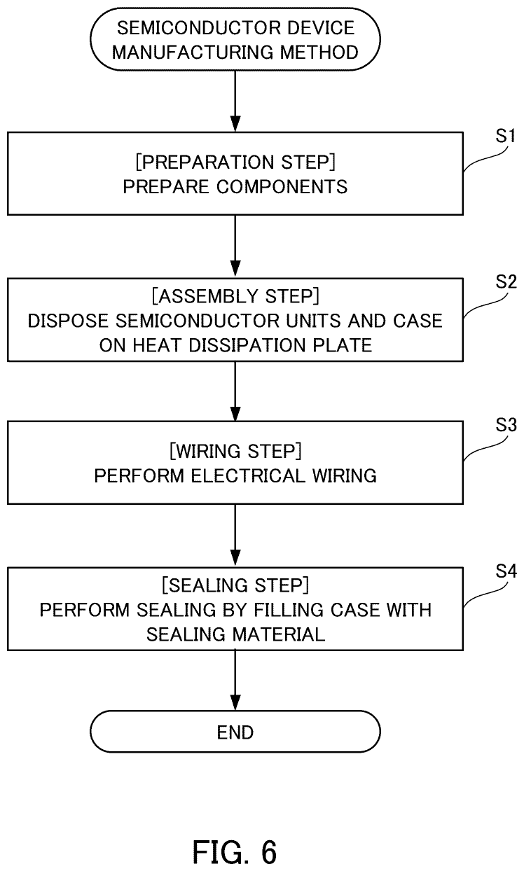

Next, a manufacturing method of the semiconductor device 1 will be described with reference to FIG. 6. FIG. 6 is a flowchart illustrating a manufacturing method of the semiconductor device according to the first embodiment. First, a preparation step of preparing components of the semiconductor device 1 and manufacturing apparatuses for manufacturing the semiconductor device 1 is performed (step S1 in FIG. 6). For example, the individual semiconductor chip 12, the individual insulated circuit board 11, the heat dissipation plate 3, the case 20, the sealing material, and the lead frames 13a and 13b, which are components of the semiconductor device 1, are prepared. The individual semiconductor unit 10 is assembled in advance by bonding the corresponding semiconductor chips 12 to the corresponding insulated circuit board 11 and by bonding the corresponding lead frames 13a and 13b to the semiconductor chips 12. In addition to these components, apparatuses used in the manufacturing method of the semiconductor device 1 are also prepared. Examples of these apparatuses s include an ultrasonic bonding apparatus, a wire bonding apparatus, and a dispensing apparatus for resin sealing. In addition to the above-described components and apparatuses, needed components, etc., may also be prepared.

Next, an assembly step of bonding the semiconductor units 10 to the heat dissipation plate 3 and disposing the case 20 on the heat dissipation plate 3 is performed (step S2 in FIG. 6). The semiconductor units 10 are bonded to the heat dissipation plate 3 via the above-described bonding material. The case 20 is attached onto the heat dissipation plate 3 via adhesive. As a result, the semiconductor units 10 are stored in the unit storage portions 21e, 21f, and 21g of the case 20.

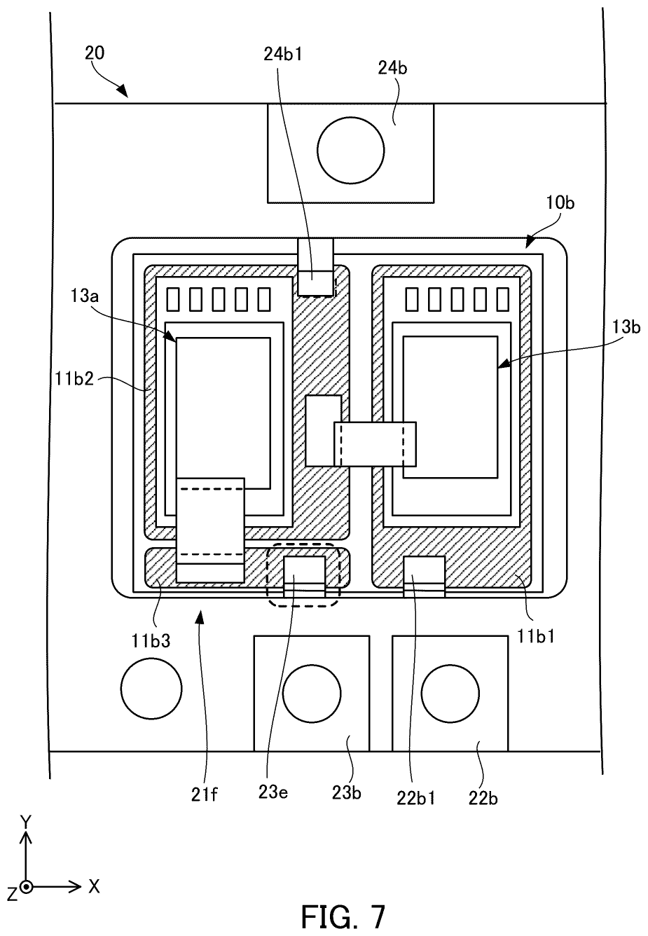

The semiconductor units 10 stored in the case 20 as described above will be described with reference to FIG. 7. FIG. 7 illustrates the assembly step included in the manufacturing method of the semiconductor device according to the first embodiment. FIG. 7 illustrates the semiconductor unit 10b stored in the unit storage portion 21f of the case 20. The semiconductor units 10a and 10c are stored in their respective unit storage portions 21e and 21g in the same way.

After step S2 in FIG. 6, in the unit storage portion 21f, a first bonding portion 22b1 (bonding portion) included in the first connection terminal 22b is disposed on the wiring plate 11b1, as illustrated in FIG. 7. A third bonding portion 24b1 (bonding portion) of the V-phase output terminal 24b is disposed on the wiring plate 11b2. In addition, a second bonding portion 23e (bonding portion) included in the second connection terminal 23b is disposed on the wiring plate 11b3.

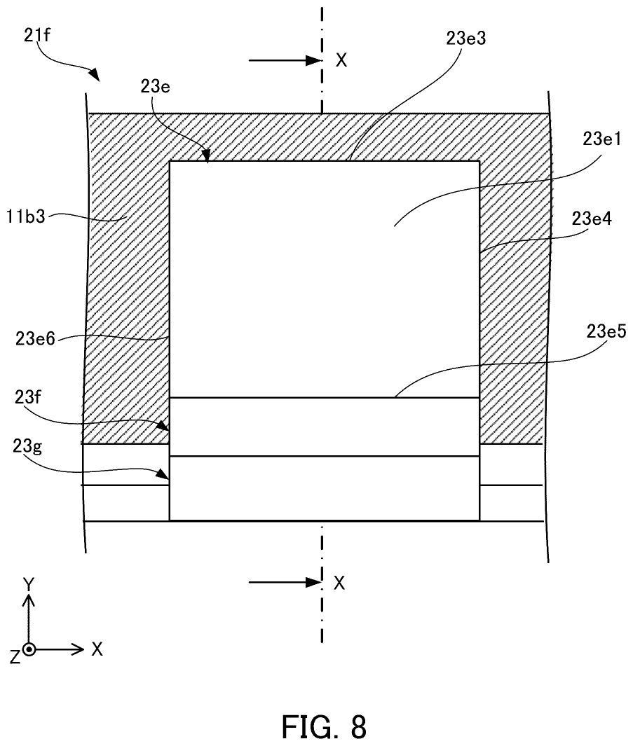

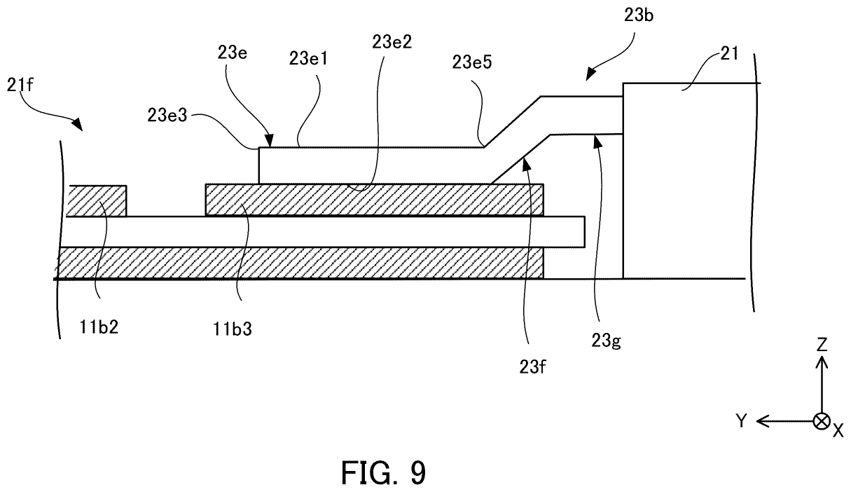

Hereinafter, as an example, the second connection terminal 23b disposed on this semiconductor unit 10 will be described in detail with reference to FIGS. 8 and 9. FIG. 8 is an enlarged plan view of the bonding portion after the assembly step included in the manufacturing method of the semiconductor device according to the first embodiment. FIG. 9 is an enlarged sectional view of the bonding portion after the assembly step included in the manufacturing method of the semiconductor device according to the first embodiment. The second bonding portion 23e included in the second connection terminal 23b in FIG. 7 and the periphery of the second bonding portion 23e are enlarged in FIG. 8. FIG. 9 is a sectional view taken along a dash-dotted line X-X in FIG. 8.

The second connection terminal 23b has approximately the same thickness as a whole (in the +Z directions), and integrally includes the second bonding portion 23e, a second linkage portion 23f (linkage portion), and a second wiring portion 23g (wiring portion). The thickness may be between 1.2 mm and 1.5 mm, inclusive.

The second bonding portion 23e has a flat plate shape. The second bonding portion 23e includes a front surface 23e1 and a rear surface 23e2, each of which has a rectangular shape in plan view. After the assembly step, which is step S2 in FIG. 6, the rear surface 23e2 of the second bonding portion 23e faces the wiring plate 11b3. The rear surface 23e2 of the second bonding portion 23e may be in contact with the wiring plate 11b3. Alternatively, there may be a gap between the rear surface 23e2 and the wiring plate 11b3, as long as the gap is small.

In addition, the second bonding portion 23e has side surfaces that sequentially surround the four sides of the front surface 23e1 and the rear surface 23e2. The four sides of the front surface 23e1, the four sides being connected to the side surfaces, are a bonding front-end side 23e3, a bonding lateral side 23e4, a bonding rear-end side 23e5, and a bonding lateral side 23e6.

The bonding front-end side 23e3 is one end of the second bonding portion 23e and faces the inside of the unit storage portion 21f (in the +Y direction) when the second bonding portion 23e is disposed on the wiring plate 11b3. The bonding rear-end side 23e5 is another end of the second bonding portion 23e and faces an inner wall of the unit storage portion 21f (the −Y direction) when the second bonding portion 23e is disposed on the wiring plate 11b3. The bonding rear-end side 23e5 is the side opposite to the bonding front-end side 23e3. The bonding front-end side 23e3 and the bonding rear-end side 23e5 may have the same length (in the +X directions).

The bonding lateral sides 23e4 and 23e6 are perpendicular to the bonding front-end side 23e3 and the bonding rear-end side 23e5, and connect the bonding front-end side 23e3 and the bonding rear-end side 23e5. The portions where two of the bonding front-end side 23e3, the bonding lateral side 23e4, the bonding rear-end side 23e5, and the bonding lateral side 23e6 are connected to each other do not need to form a right angle. These portions may be rounded.

The second linkage portion 23f links the second bonding portion 23e and the second wiring portion 23g. The second linkage portion 23f is integrally connected to a side surface of the second bonding portion 23e, the side surface being near the bonding rear-end side 23e5, and rises in the +Z direction from the front surface 23e1 of the second bonding portion 23e.

The second wiring portion 23g is connected to an end of the second linkage portion 23f, and extends to the outside from the unit storage portion 21f in plan view. The second wiring portion 23g extends inside the outer frame 21 and appears from the front surface of the outer frame 21.

The second connection terminal 23b is disposed on the wiring plate 11b3 as described above. Although not illustrated, the second connection terminals 23a and 23c, the first connection terminals 22a, 22b, and 22c, the U-phase output terminal 24a, the V-phase output terminal 24b, and the W-phase output terminal 24c are constructed in the same way.

Next, a wiring step of wiring the semiconductor units 10 is performed (step S3 in FIG. 6). In this wiring step, various kinds of terminals and the semiconductor units 10 are electrically wired by using wiring members.

First, the control electrodes 12a of the semiconductor chips 12 included in the individual semiconductor units 10 stored in the case 20 are bonded to the control terminals 25a, 25b, and 25c by the wires 26 by using a bonding apparatus. As a result of this bonding, the wires 26 extend as illustrated in FIG. 1.

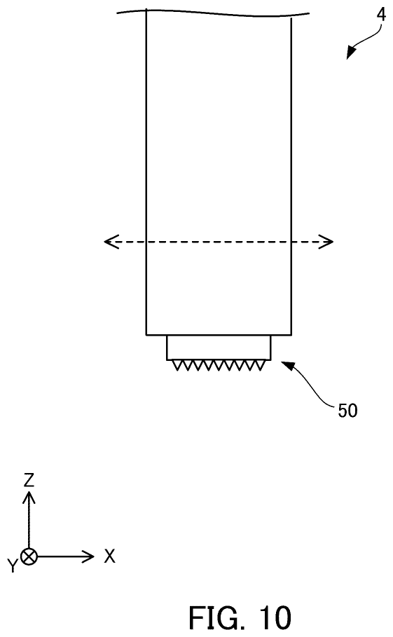

The bonding portions of the individual terminals disposed on the wiring plates 11b1, 11b2, and 11b3 of the individual semiconductor units 10 are bonded to the wiring plates 11b1, 11b2, and 11b3 by ultrasonic bonding of an ultrasonic bonding apparatus. Hereinafter, a bonding tool included in the ultrasonic bonding apparatus will be described with reference to FIGS. 10 to 13B.

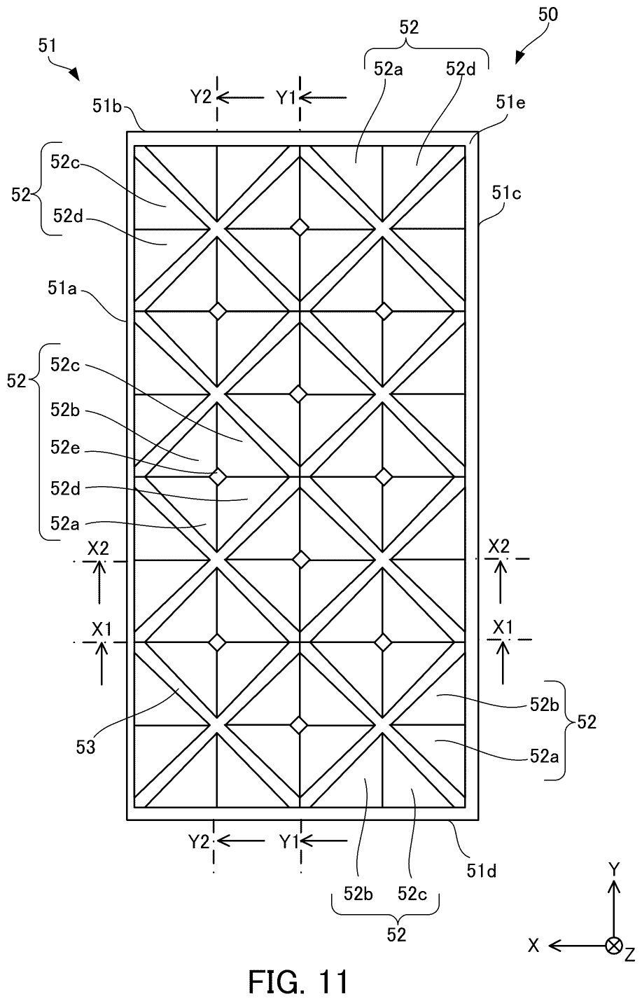

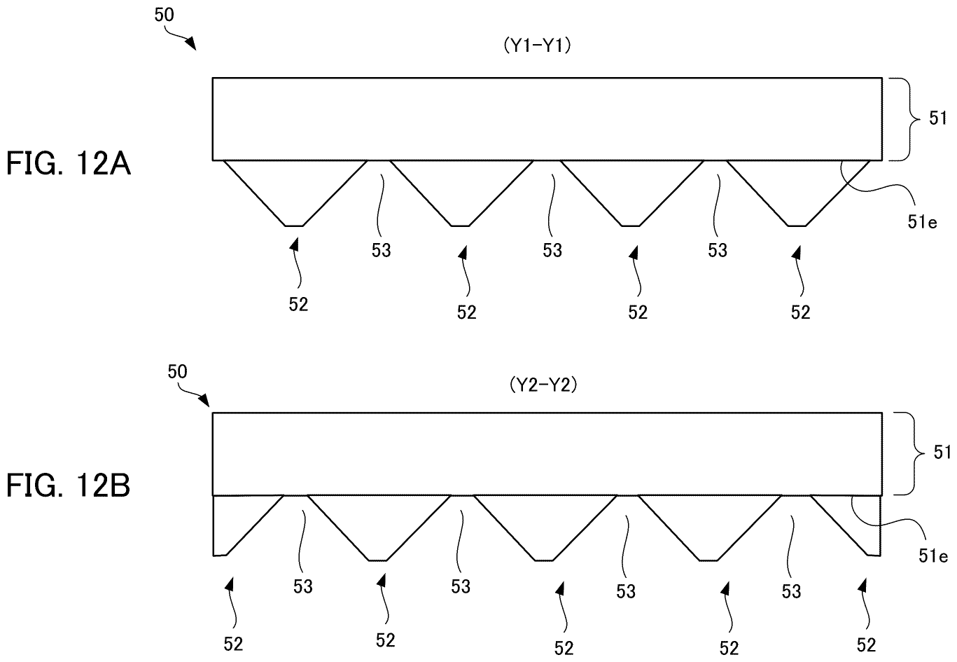

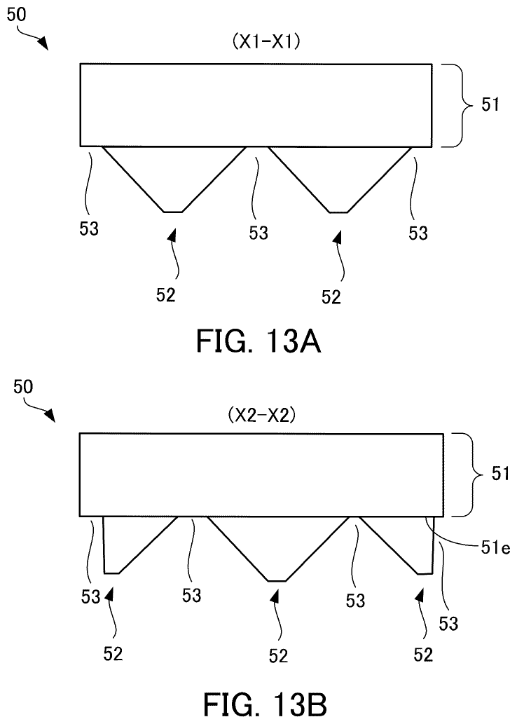

FIG. 10 is a side view of a bonding tool used in the wiring step included in the manufacturing method of the semiconductor device according to the first embodiment. FIG. 11 is a plan view of a bonding tip portion of the bonding tool used in the wiring step included in the manufacturing method of the semiconductor device according to the first embodiment. FIGS. 12A and 12B are first sectional views of the bonding tip portion of the bonding tool used in the wiring step included in the manufacturing method of the semiconductor device according to the first embodiment. FIGS. 13A and 13B are second sectional views of the bonding tip portion of the bonding tool used in the wiring step included in the manufacturing method of the semiconductor device according to the first embodiment. Specifically, FIG. 10 is a side view of a tip portion of a bonding tool 4 seen in the +Y direction. FIG. 11 is a plan view (of the rear surface) of the bonding tool 4 seen in the +Z direction. FIGS. 12A and 12B are sectional views taken along dash-dotted lines Y1-Y1 and Y2-Y2 in FIG. 11. FIGS. 13A and 13B are sectional views taken along dash-dotted lines X1-X1 and X2-X2 in FIG. 11.

The bonding tool 4 illustrated in FIG. 10 is included in an ultrasonic bonding apparatus. The bonding tool 4 has a columnar shape and vibrates in a predetermined direction by a vibration generator included in the same ultrasonic bonding apparatus. The columnar shape may be a cylindrical shape or a polygonal shape. The predetermined direction may be a direction parallel to the X-Y plane.

The bonding tool 4 includes a bonding tip portion 50 at its tip portion (in the −Z direction in FIG. 10). The bonding tip portion 50 is brought in contact with a bonding target object and presses the bonding target object while vibrating in a specified direction. In this way, bonding is performed.

As illustrated in FIG. 11 and FIGS. 12A and 12B, the bonding tip portion 50 includes a bonding base 51 and a plurality of protrusions 52. The bonding base 51 and the plurality of protrusions 52 included in the bonding tip portion 50 may be made of the same material. Examples of the material include a cemented carbide material. For example, the cemented carbide material is tungsten, tungsten carbide, or an alloy containing at least one of these kinds of elements.

The bonding base 51 is located at a tip of the bonding tip portion 50, and this tip comes in contact with a bonding target object. The bonding base 51 has a rectangular shape in plan view, and includes a flat tip surface 51e, which is approximately parallel to the X-Y plane, and side surfaces surrounding the tip surface 51e in four directions. The portions where the side surfaces are connected to the tip surface 51e include a pressing lateral side 51a, a pressing front-end side 51b, a pressing lateral side 51c, and a pressing rear-end side 51d. The pressing front-end side 51b and the pressing rear-end side 51d have the same ±X direction length, and this length is less than the ±X direction length of the second bonding portion 23e of the above-described second connection terminal 23b.

The plurality of protrusions 52 may be formed integrally on the tip surface 51e. That is, the tip surface 51e of the bonding base 51 includes a group of concave portions and convex portions as the plurality of protrusions 52. Each protrusion 52 is shaped like a rectangular pyramid and includes side surfaces 52a to 52d. The individual protrusion 52 in this case includes a flat pressing surface 52e at its top portion. Among the plurality of protrusions 52, those disposed along the periphery of the tip surface 51e are each shaped like half of a rectangular pyramid. The protrusions 52 disposed along the pressing lateral side 51a of the tip surface 51e each include side surfaces 52c and 52d. The protrusions 52 disposed along the pressing front-end side 51b of the tip surface 51e each include side surfaces 52a and 52d. The protrusions 52 disposed along the pressing lateral side 51c of the tip surface 51e each include side surfaces 52a and 52b. The protrusions 52 disposed along the pressing rear-end side 51d of the tip surface 51e each include side surfaces 52b and 52c.

The plurality of protrusions 52 may be formed in a zigzag pattern or in a grid pattern. These are examples of the arrangement of the plurality of protrusions 52. Although the protrusions 52 have a rectangular pyramid shape in FIG. 11, this is only an example. The protrusions 52 may have a polygonal pyramid shape or a conical shape. These protrusions 52 are formed on the tip surface 51e such that a gap 53 is formed between protrusions 52. The plurality of protrusions 52 have approximately the same height. This height is from the tip surface 51e to the pressing surface 52e of each protrusion 52. The pressing surfaces 52e of the plurality of protrusions 52 are on the same plane.

In addition, the height of the plurality of protrusions 52 from the tip surface 51e is between 15% and 90%, inclusive, of the thickness of the bonding target object. If bonding is performed with the bonding tip portion 50 including the plurality of protrusions 52 whose height from the tip surface 51e is less than 15% of the thickness of the bonding target object, the bonding target object is ground and damaged. In addition, if the height of the plurality of protrusions 52 from the tip surface 51e exceeds 90% of the thickness of the bonding target object, the bonding target object could be fractured. In the present embodiment, the height of the plurality of protrusions 52 from the tip surface 51e is 0.15 mm or greater, for example.

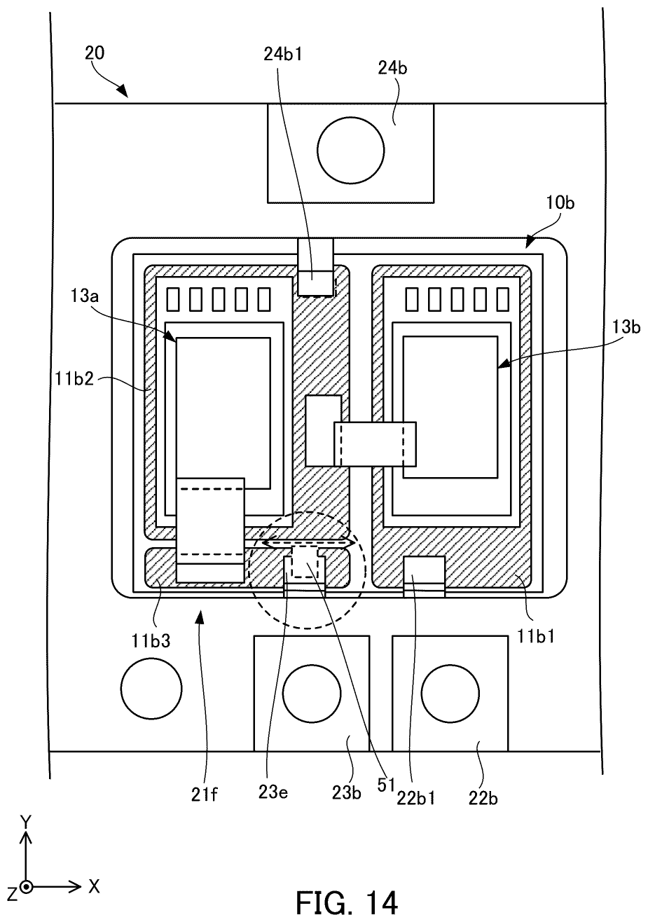

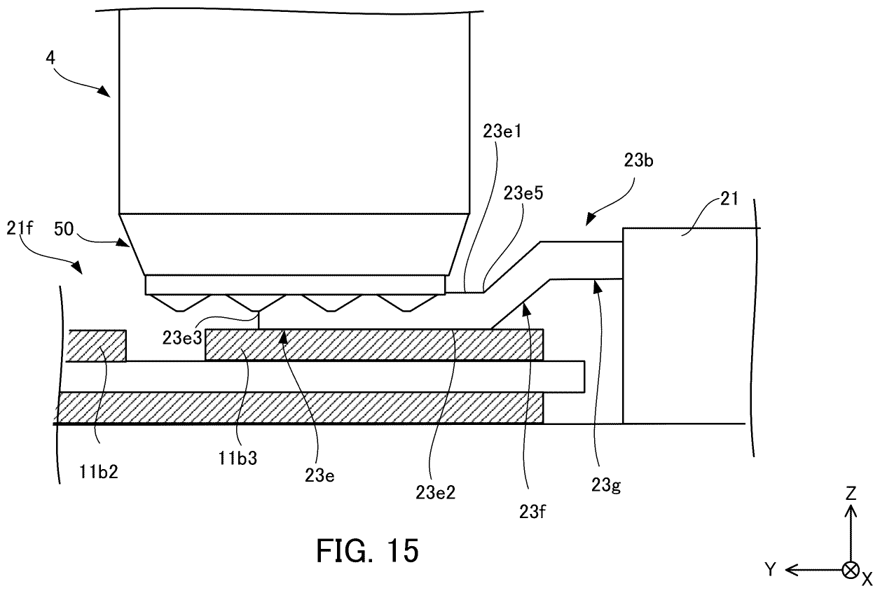

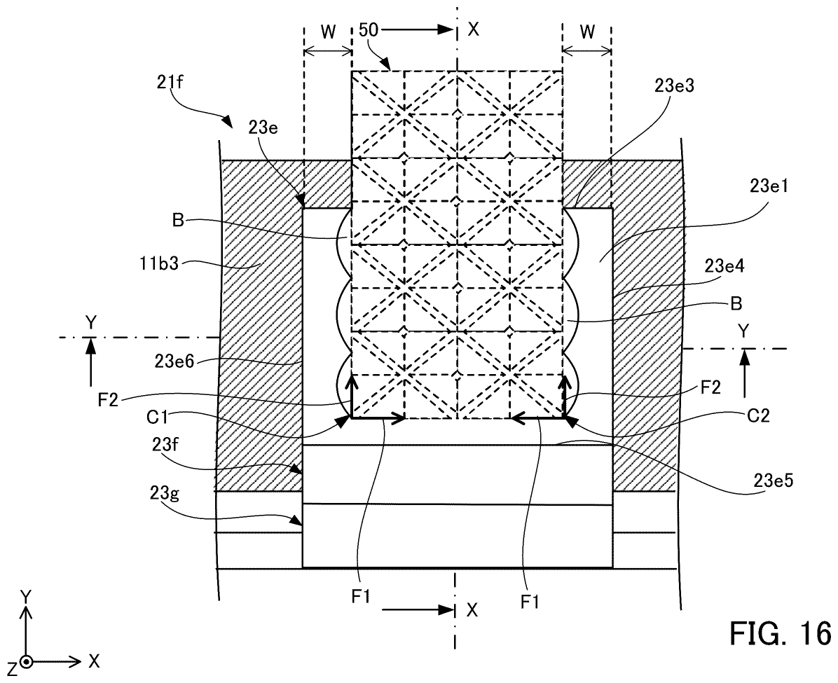

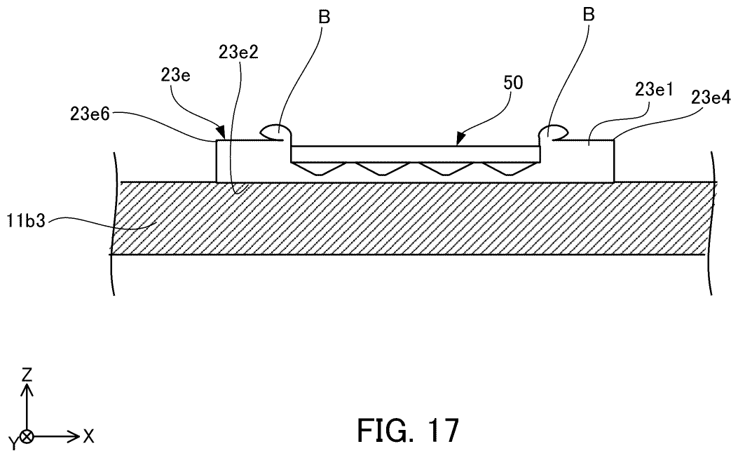

Bonding performed with the bonding tool 4 in the wiring step will be described with reference to FIGS. 14 to 17. FIG. 14 is a plan view illustrating the wiring step (at bonding) included in the manufacturing method of the semiconductor device according to the first embodiment. FIG. 15 is a sectional view illustrating the wiring step (at bonding) included in the manufacturing method of the semiconductor device according to the first embodiment. FIG. 16 is a plan view of a main part, illustrating the wiring step (at bonding) included in the manufacturing method of the semiconductor device according to the first embodiment. FIG. 17 is a sectional view of the main part, illustrating the wiring step (at bonding) included in the manufacturing method of the semiconductor device according to the first embodiment. The following description will be made on the bonding of the second bonding portion 23e of the second connection terminal 23b to the wiring plate 11b3. The bonding of other bonding portions to the wiring plates 11b1 and 11b2 will be performed in the same way.

In FIG. 14, a dashed rectangle on the front surface of the second bonding portion 23e of the second connection terminal 23b indicates the location where the bonding base 51 of the bonding tool 4 is set. FIG. 15 is sectional view of FIG. 14, taken along the dash-dotted line X-X in FIG. 8. FIG. 16 is an enlarged view of the second bonding portion 23e in a dashed circle in FIG. 14. In FIG. 16, the location where the bonding tip portion 50 (and the plurality of protrusions 52) is disposed is indicated by dashed lines. FIG. 17 is a sectional view taken along a dash-dotted line Y-Y in FIG. 16. In FIG. 17, only the bonding tip portion 50 of the bonding tool 4 pressing the second bonding portion 23e is illustrated.

To bond the second bonding portion 23e of the second connection terminal 23b to the wiring plate 11b3 of the insulated circuit board 11, the bonding tip portion 50 of the bonding tool 4 is set on the front surface 23e1 of the second bonding portion 23e. As illustrated in FIGS. 14 and 15, the pressing front-end side 51b of the bonding tip portion 50 (the bonding base 51) is located on a more outer side than the bonding front-end side 23e3 of the second bonding portion 23e (in the +Y direction, that is, in the direction of the center of the unit storage portion 21f). In addition, the pressing lateral sides 51a and 51c of the bonding tip portion 50 (the bonding base 51) are located inside the bonding lateral sides 23e4 and 23e6 of the second bonding portion 23e (in the ±X directions).

In this state, the second bonding portion 23e of the second connection terminal 23b is pressed to the wiring plate 11b3 of the insulated circuit board 11 while being vibrated by the bonding tip portion 50 of the bonding tool 4 with a predetermined vibration frequency.

As a result, as illustrated in FIGS. 16 and 17, the bonding tip portion 50 of the bonding tool 4 penetrates into the front surface 23e1 of the second bonding portion 23e of the second connection terminal 23b, and burrs B occur from the pressing lateral sides 51a and 51c of the bonding tip portion 50 (the bonding base 51).

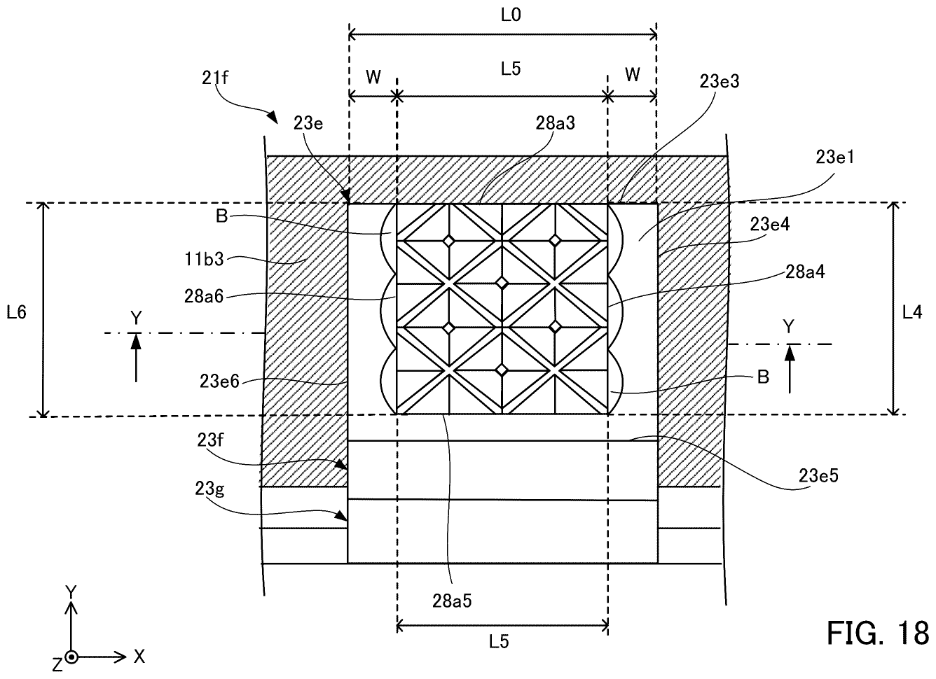

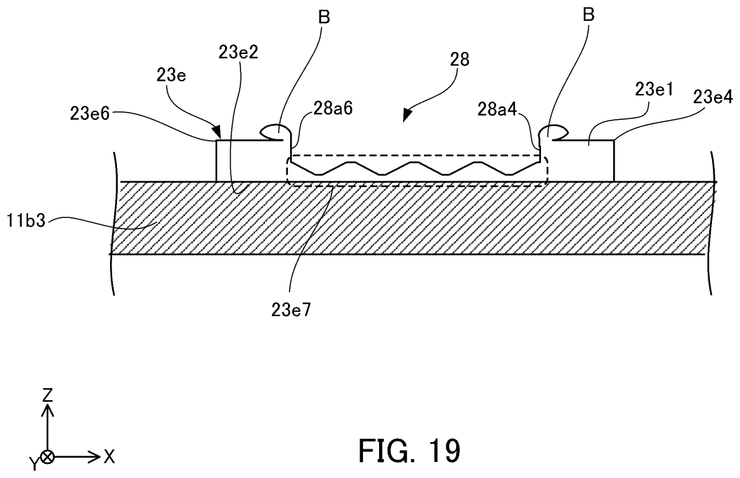

As described above, the second bonding portion 23e of the second connection terminal 23b is bonded to the wiring plate 11b3 of the insulated circuit board 11. The state obtained after this bonding will be described with reference to FIGS. 18 and 19. FIG. 18 is a plan view of the main part, illustrating the wiring step (after bonding) included in the manufacturing method of the semiconductor device according to the first embodiment. FIG. 19 is a sectional view of the main part, illustrating the wiring step (after bonding) included in the manufacturing method of the semiconductor device according to the first embodiment. FIGS. 18 and 19 illustrate the state obtained after the bonding is performed as illustrated in FIGS. 16 and 17 and the bonding tool 4 is removed. FIG. 19 is a sectional view taken along a dash-dotted line Y-Y in FIG. 18.

After the second bonding portion 23e of the second connection terminal 23b is bonded to the wiring plate 11b3 of the insulated circuit board 11 by using the bonding tool 4 as described with reference to FIGS. 16 and 17, the bonding tool 4 is removed. As a result, as illustrated in FIGS. 18 and 19, an indentation 28 is generated on the front surface 23e1 of the second bonding portion 23e of the second connection terminal 23b.

As illustrated in FIG. 18, the indentation 28 is a result of the transfer of the group of concave portions and convex portions of the plurality of protrusions 52 included in the bonding tip portion 50 of the bonding tool 4 to the front surface 23e1 of the second bonding portion 23e of the second connection terminal 23b. The second bonding portion 23e has an indentation portion 23e7 to which the indentation 28 has been transferred. The indentation portion 23e7 is a concave portion with respect to the front surface 23e1 of the second bonding portion 23e of the second connection terminal 23b, and is located below the front surface 23e1, as illustrated in FIG. 19. The depth from the front surface 23e1 of the second bonding portion 23e of the indentation portion 23e7 is between 250 μm and 700 μm, inclusive, for example. In plan view, the indentation 28 includes an indentation front-end side 28a3, an indentation lateral side 28a4, and indentation rear-end side 28a5, and an indentation lateral side 28a6.

The indentation front-end side 28a3 is one end of the indentation 28 (in the +Y direction, that is, in the direction of the center of the unit storage portion 21f). The indentation front-end side 28a3 is on the same plane with the bonding front-end side 23e3 of the second bonding portion 23e of the second connection terminal 23b. The +X direction length of the indentation rear-end side 28a5 is L5.

The indentation rear-end side 28a5 is another end of the indentation 28 (in the −Y direction), and this end is opposite to the indentation front-end side 28a3. The +X direction length of the indentation rear-end side 28a5 is L5, which the same as the ±X direction length of the indentation front-end side 28a3. The length L5 of the indentation rear-end side 28a5 is less than a length L0 of the bonding rear-end side 23e5 of the second bonding portion 23e of the second connection terminal 23b.

The indentation lateral sides 28a4 and 28a6 are each perpendicular to the indentation front-end side 28a3 and the indentation rear-end side 28a5 and each connect the indentation front-end side 28a3 and the indentation rear-end side 28a5. Lengths L4 and L6 of the indentation lateral sides 28a4 and 28a6 are the same (in the +Y directions). The indentation lateral sides 28a4 and 28a6 are located inside the bonding lateral sides 23e4 and 23e6 of the second bonding portion 23e of the second connection terminal 23b in the +X directions. The distance between the indentation lateral side 28a4 and the bonding lateral side 23e4 of the second bonding portion 23e of the second connection terminal 23b is W. The distance between the indentation lateral side 28a6 and the bonding lateral side 23e6 of the second bonding portion 23e of the second connection terminal 23b is also W. For example, the distance W may be 1 mm or greater, more preferably, 1.5 mm or greater. A burr B may be generated along each of the indentation lateral sides 28a4 and 28a6. FIGS. 18 and 19 illustrate a case in which a burr B continuously extends to the outside (in the direction of the bonding lateral sides 23e4 and 23e6 of the second bonding portion 23e) along each of the entire indentation lateral sides 28a4 and 28a6. The shape, the size, the length in the ±X directions, the length in the ±Y directions, and the thickness in the ±Z directions of these burrs B are only examples. These burrs B may be generated discontinuously along the indentation lateral sides 28a4 and 28a6. The length of the burrs B extending to the outside from the indentation lateral sides 28a4 and 28a6 may differ depending on the location of the indentation lateral sides 28a4 and 28a6 (in the ±Y directions). The burrs B extending from the indentation lateral sides 28a4 and 28a6 do not need to be symmetrical to each other.

Next, a sealing step of injecting sealing material into the unit storage portions 21e, 21f, and 21g of the case 20 in which the semiconductor units 10 are stored and sealing the semiconductor units 10 is performed (step S4 in FIG. 6). After the unit storage portions 21e, 21f, and 21g are filled with the sealing material, the sealing material is cured to seal the semiconductor units 10, etc. As a result, the semiconductor device 1 is obtained.

Hereinafter, a manufacturing method of a semiconductor device 1 according to a reference example will be described. The semiconductor device 1 according to the reference example may also be manufactured in accordance with the flowchart in FIG. 6. However, in the reference example, the ±X direction length of a bonding base 51 of a bonding tip portion 50 of a bonding tool 4 is greater than the ±X direction length of the bonding portion of the individual terminal. Accordingly, a plurality of protrusions 52 are formed uniformly on the expanded bonding base 51. In the other aspects, the semiconductor device 1 and the manufacturing method thereof according to the reference example are the same as those according to the first embodiment.

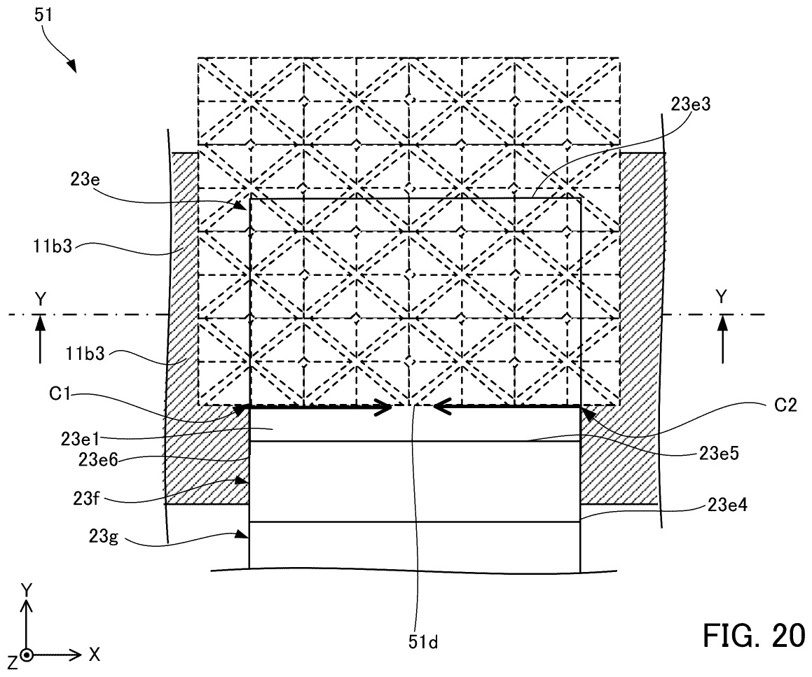

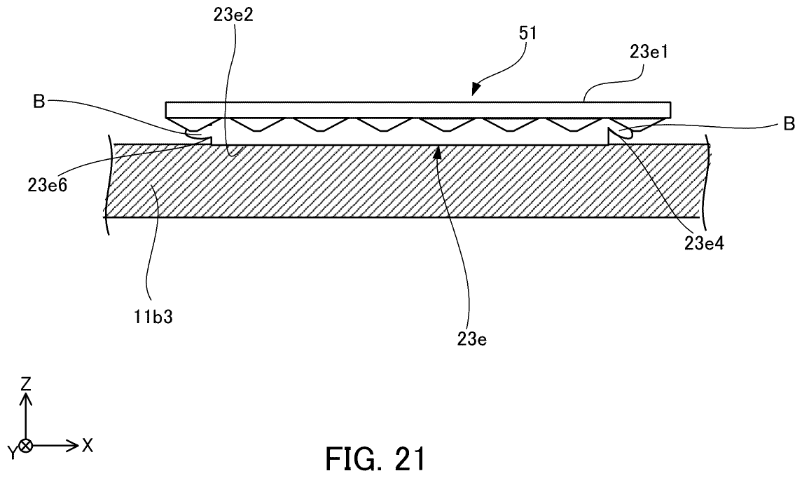

As in the first embodiment, the preparation step of step S1 and the assembly step of step S2 are performed. Next, the wiring step of wiring the semiconductor units 10 is performed (step S3 in FIG. 6). The bonding between the second bonding portion 23e of the second connection terminal 23b and the wiring plate 11b3 by the bonding tool 4, the bonding being included in the wiring step, will be described with reference to FIGS. 20 and 21.

FIG. 20 is a plan view of a main part, illustrating the wiring step (at bonding) included in the manufacturing method of the semiconductor device according to the reference example. FIG. 21 is a sectional view of the main part, illustrating the wiring step (at bonding) included in the manufacturing method of the semiconductor device according to the reference example. FIGS. 20 and 21 correspond to FIGS. 16 and 17, respectively. In FIG. 20, the location where the bonding tip portion 50 (and the plurality of protrusions 52) is disposed is indicated by a dashed line. FIG. 21 is a sectional view taken along a dash-dotted line Y-Y in FIG. 20.

As in the first embodiment, the bonding tip portion 50 of the bonding tool 4 is set on the front surface 23e1 of the second bonding portion 23e. Next, the second bonding portion 23e of the second connection terminal 23b is pressed to the wiring plate 11b3 of the insulated circuit board 11 while being vibrated by the bonding tip portion 50 of the bonding tool 4 with a predetermined vibration frequency.

As a result, as illustrated in FIGS. 20 and 21, the bonding tip portion 50 of the bonding tool 4 penetrates into the front surface 23e1 of the second bonding portion 23e of the second connection terminal 23b, and burrs B occur from the bonding lateral sides 23e4 and 23e6 of the second bonding portion 23e and extend to the outside (in the +X directions).

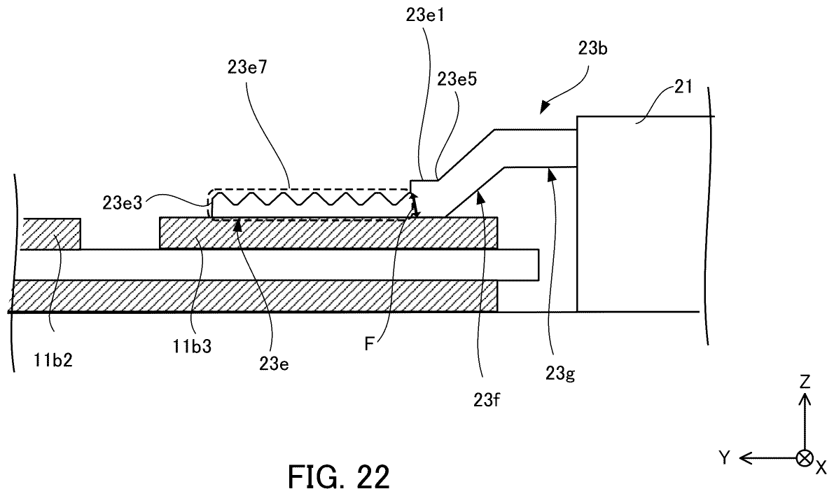

The state obtained after the above-described bonding is performed and the bonding tool 4 is removed will be described with reference to FIG. 22. FIG. 22 illustrates a side surface of the main part, illustrating the wiring step (after bonding) included in the manufacturing method of the semiconductor device according to the reference example. Specifically, FIG. 22 is a side view of the second bonding portion 23e of the second connection terminal 23b bonded to the wiring plate 11b3, seen in the +X direction. Although a plan view of the front surface 23e1 of the second bonding portion 23e of the second connection terminal 23b in this case is not illustrated, according to the reference example, the indentation lateral sides 28a4 and 28a6 of the indentation 28 match the bonding lateral sides 23e4 and 23e6 of the second bonding portion 23e of the second connection terminal 23b in FIG. 18.

After the bonding in the wiring step in step S3, as illustrated in FIG. 22, the indentation 28 is generated on the front surface 23e1 of the second bonding portion 23e of the second connection terminal 23b. Next, the sealing step in step S4 is performed to manufacture the semiconductor device 1.

If a thermal cycling test is conducted on this semiconductor device 1, internal stress occurs due to the difference in linear expansion coefficient among the components of the semiconductor device 1. This stress also occurs in the bonding portions of the terminals bonded to the wiring plates 11b1, 11b2, and 11b3.

For example, in the manufacturing method of the semiconductor device 1 according to the reference example, as illustrated in FIG. 20, when the front surface 23e1 of the second bonding portion 23e of the second connection terminal 23b is pressed by the bonding tip portion 50 of the bonding tool 4, the bonding tip portion 50 causes cracks at corner portion C1 and C2 of the front surface 23e1 of the second bonding portion 23e, and the cracks extend along arrows from the corner portions C1 and C2.

A thermal cycling test is conducted on the semiconductor device 1 including the second connection terminal 23b including these cracks. The second connection terminal 23b has the second bonding portion 23e fixed to the wiring plate 11b3, and the second wiring portion 23g is fixed to the outer frame 21. If warpage occurs in the semiconductor device 1, stress occurs in the second connection terminal 23b. As a result, the cracks in the second connection terminal 23b extend along an arrow F in FIG. 22, and the second bonding portion 23e is fractured, leaving the indentation portion 23e7 of the second bonding portion 23e, to which the indentation 28 has been transferred, on the wiring plate 11b3. Thus, in the case of the reference example, the semiconductor device 1 has a shorter lifetime and a lower long-term reliability.

In contrast, the pressing front-end side 51b of the bonding tip portion 50 (the bonding base 51) of the bonding tool 4 used in the manufacturing method of the semiconductor device 1 according to the first embodiment is located on a more outer side than the bonding front-end side 23e3, which is one end of the second bonding portion 23e, and the length of the pressing rear-end side 51d opposite to the pressing front-end side 51b is less than the length of the bonding rear-end side 23e5, which is another end of the second bonding portion 23e.

When the front surface 23e1 of the second bonding portion 23e of the second connection terminal 23b is pressed by the bonding tip portion 50 of the bonding tool 4, as in the reference example, cracks occur at corner portions C1 and C2 of the front surface 23e1 of the second bonding portion 23e, and the cracks extend along arrows from the corner portions C1 and C2 (see FIG. 16). However, in this case, because the length of the pressing rear-end side 51d opposite the pressing front-end side 51b is less than the bonding rear-end side 23e5, which is another end of the second bonding portion 23e, the stress applied to the corner portions C1 and C2 is distributed in two directions (arrows F1 and F2 in FIG. 16). Thus, the extension of the cracks in their respective directions is delayed. Thus, even when a thermal cycling test is conducted on the semiconductor device 1 according to the first embodiment, the extension of the cracks is delayed, and the fracture of the second connection terminal 23b (the second bonding portion 23e) is delayed. As a result, the reduction in the lifetime of the semiconductor device 1 according to the first embodiment is prevented and the long-term reliability is improved.

In addition, the bonding tip portion 50 of the bonding tool 4 has a smaller pressing area than that of the bonding tip portion 50 used in the reference example. Therefore, the volume pressing the front surface 23e1 of the second bonding portion 23e of the second connection terminal 23b is also reduced. As a result, the quantity of the burrs B generated on the front surface 23e1 of the second bonding portion 23e of the second connection terminal 23b is also reduced. These burrs B could come in contact with other electrically conductive components, depending on the extension of the burrs B. In addition, these burrs B could cause noise. In the manufacturing method of the semiconductor device 1 according to the first embodiment, since the quantity of burrs B generated is reduced, the possibility that a burr B comes in contact with another electrically conductive component is reduced, and generation of the noise is accordingly reduced.

The semiconductor device 1 manufactured by the above-described manufacturing method includes the wiring plate 11b3 and the second connection terminal 23b. The second connection terminal 23b includes the flat-plate-shaped second bonding portion 23e having the rear surface 23e2 bonded to the wiring plate 11b3 and having the front surface 23e1 on which the indentation 28 is formed. The indentation front-end side 28a3, which is one end of the indentation 28, is on the same plane with the bonding front-end side 23e3, which is one end of the second bonding portion 23e. The length of the indentation rear-end side 28a5, which is another end of the indentation 28 and is opposite to the indentation front-end side 28a3, is less than the length of the bonding rear-end side 23e5, which is another end of the second bonding portion 23e and is opposite to the bonding front-end side 23e3. In this way, the extension of cracks that occur at the bonding rear-end side 23e5 of the second bonding portion 23e is delayed. As a result, the reduction in the lifetime of the semiconductor device 1 according to the first embodiment is prevented, and the long-term reliability is improved.

In addition, it is preferable that a sum of the length L5 of the indentation rear-end side 28a5 and the lengths L4 and L6 of the indentation lateral sides 28a4 and 28a6 of the indentation 28 (L4+L5+L6) be greater than the length L0 of the bonding front-end side 23e3 of the second bonding portion 23e of the second connection terminal 23b. In this way, the extension of the cracks is further delayed.

In addition, as described above, the distance W between the indentation lateral side 28a4 and the bonding lateral side 23e4 of the second bonding portion 23e of the second connection terminal 23b may be, for example, 1 mm or greater, more preferably, 1.5 mm or greater. The same applies to the distance W between the indentation lateral side 28a6 and the bonding lateral side 23e6. For example, if this distance W is greater than 0 mm and is 0.5 mm or less, a thermal cycling test easily fractures portions adjacent to the indentation portion 23e7 of the second bonding portion 23e in the ±X directions. This could be because the strength deteriorates as the volume of the portions adjacent to the indentation portion 23e7 (see FIG. 19) of the second bonding portion 23e in ±X directions reduces. Thus, it is preferable that the distance W between the indentation lateral side 28a4 and the bonding lateral side 23e4 of the second bonding portion 23e of the second connection terminal 23b be between 1 mm and 1.5 mm, inclusive. The same applies to the distance W between the indentation lateral side 28a6 and the bonding lateral side 23e6.

### Second Embodiment

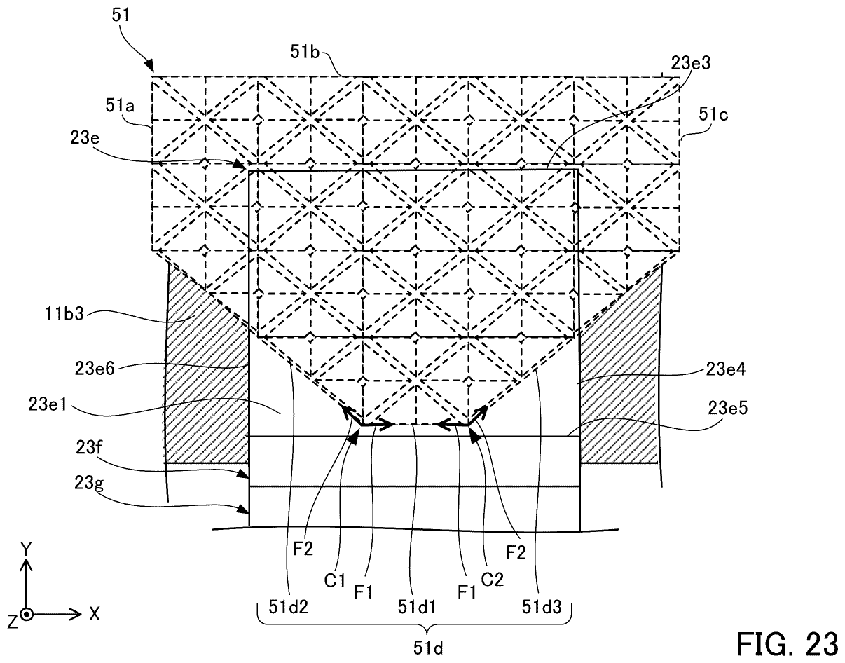

In a second embodiment, a manufacturing method of a semiconductor device 1, the manufacturing method using a bonding tip portion 50 of a bonding tool 4 having a different shape from that according to the first embodiment, will be described with reference to FIG. 23. FIG. 23 is a plan view of a main part, illustrating a wiring step (at bonding) included in a manufacturing method of a semiconductor device according to a second embodiment.

It is possible to manufacture the semiconductor device according to the second embodiment in accordance with the flowchart in FIG. 6. However, the planar shape of a bonding base 51 of the bonding tip portion 50 of the bonding tool 4 according to the second embodiment differs from that according to the first embodiment.

The bonding base 51 according to the second embodiment has a hexagonal shape in plan view, and a side of the bonding base 51, the side facing the bonding rear-end side 23e5 of the second connection terminal 23b, protrudes toward the bonding rear-end side 23e5. That is, the bonding base 51 according to the second embodiment includes a flat tip surface 51e approximately parallel to the X-Y plane and side surfaces surrounding the tip surface 51e in four directions. As illustrated in FIG. 23, the portions where the side surfaces and the tip surface 51e are connected include a pressing lateral side 51a, a pressing front-end side 51b, a pressing lateral side 51c, and a pressing rear-end side 51d.

The pressing front-end side 51b is located on a more outer side than the bonding front-end side 23e3 of the second bonding portion 23e of the second connection terminal 23b (in the +Y direction). The ±X direction length of the pressing front-end side 51b is greater than the ±X direction length of the bonding front-end side 23e3 of the second bonding portion 23e of the second connection terminal 23b.

The pressing lateral sides 51a and 51c are connected to the ±X direction ends of the pressing front-end side 51b, and are perpendicular to the pressing front-end side 51b. The pressing lateral sides 51a and 51c have the same length (in the ±Y direction), which is not limited to any particular length, as long as the angle of the connection between a pressing center portion 51d1 and pressing lateral portions 51d2 and 51d3, which will be described below, is less than 90°.

The pressing rear-end side 51d has its both ends connected to the pressing lateral sides 51a and 51c. The pressing rear-end side 51d further includes the pressing center portion 51d1 and the pressing lateral portions 51d2 and 51d3. The pressing center portion 51d1 is the center portion of the pressing rear-end side 51d and is parallel to the pressing front-end side 51b. The ±X direction length of the pressing center portion 51d1 is less than the ±X direction length of the bonding rear-end side 23e5 of the second bonding portion 23e of the second connection terminal 23b. In addition, the pressing center portion 51d1 is closer to the bonding rear-end side 23e5 of the second bonding portion 23e than the −Y direction ends of the pressing lateral sides 51a and 51c. That is, the pressing center portion 51d1 of the pressing rear-end side 51d protrudes in the direction opposite to the pressing front-end side 51b.

The pressing lateral portions 51d2 and 51d3 connect the ±X direction ends of the pressing center portion 51d1 and the −Y direction ends of the pressing lateral sides 51a and 51c. Although the length of the pressing lateral portions 51d2 and 51d3 depends on how the pressing center portion 51d1 protrudes, the pressing lateral portions 51d2 and 51d3 have the same length. The pressing lateral portions 51d2 and 51d3 are connected to the pressing center portion 51d1 at an angle less than 90°.

Corner portions C1 and C2 are formed where the pressing center portion 51d1 and the pressing lateral portions 51d2 and 51d3 are connected. The angle of each of the corner portions C1 and C2 is greater than the angle of each of the corner portions C1 and C2 according to the first embodiment. The angle of each of the corner portions C1 and C2 is greater than 90°.

A plurality of protrusions 52 are uniformly formed on the entire tip surface 51e of the bonding base 51. In addition, according to the second embodiment, the plurality of protrusions 52 also have approximately the same height. This height is from the tip surface 51e to a pressing surface 52e of each of the protrusions 52. The pressing surfaces 52e of the plurality of protrusions 52 are on the same plane.

Bonding is performed in the wiring step in step S3 in FIG. 6 by using the above-described bonding tool 4. The bonding tip portion 50 of the bonding tool 4 according to the second embodiment is set on the front surface 23e1 of the second bonding portion 23e (see FIG. 23).

In this state, the second bonding portion 23e of the second connection terminal 23b is pressed to the wiring plate 11b3 of the insulated circuit board 11 while being vibrated by the bonding tip portion 50 of the bonding tool 4 with a predetermined vibration frequency.

As a result, as illustrated in FIG. 23, the bonding tip portion 50 of the bonding tool 4 penetrates into the front surface 23e1 of the second bonding portion 23e of the second connection terminal 23b. In this case, too, although not illustrated, burrs B occur at portions near the bonding lateral sides 23e4 and 23e6 of the second connection terminal 23b (the second bonding portion 23e), the portions that come in contact with the bonding tip portion 50 (the bonding base 51).

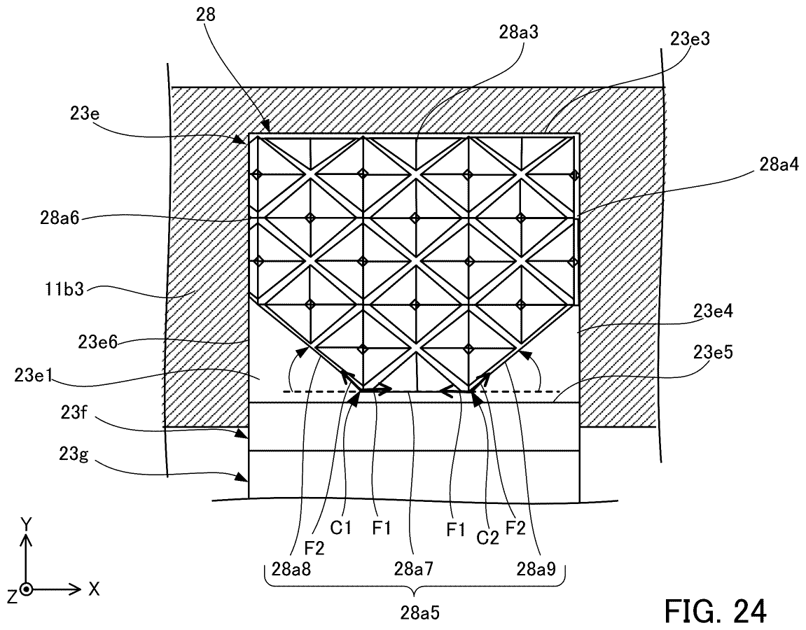

As described above, the second bonding portion 23e of the second connection terminal 23b is bonded to the wiring plate 11b3 of the insulated circuit board 11. The state obtained after this bonding will be described with reference to FIG. 24. FIG. 24 is a plan view of the main part, illustrating the wiring step (after bonding) included in the manufacturing method of the semiconductor device according to the second embodiment. FIG. 24 illustrates the front surface 23e1 of the second bonding portion 23e of the second connection terminal 23b after the bonding tool 4 in FIG. 23 is removed. The illustration of the burrs B is omitted in FIG. 24.

After the second bonding portion 23e of the second connection terminal 23b is bonded to the wiring plate 11b3 of the insulated circuit board 11 by using the bonding tool 4 as described with reference to FIG. 23, the bonding tool 4 is removed. As a result, as illustrated in FIG. 24, an indentation 28 is generated on the front surface 23e1 of the second bonding portion 23e of the second connection terminal 23b.

The indentation 28 is a result of the transfer of the group of concave portions and convex portions of the plurality of protrusions 52 included in the bonding tip portion 50 of the bonding tool 4 to the front surface 23e1 of the second bonding portion 23e of the second connection terminal 23b. The second bonding portion 23e has an indentation portion to which the indentation 28 has been transferred. Although not illustrated, the indentation portion is a concave portion with respect to the front surface 23e1 of the second bonding portion 23e of the second connection terminal 23b, and is located below the front surface 23e1. In plan view, the indentation 28 includes an indentation front-end side 28a3, an indentation lateral side 28a4, an indentation rear-end side 28a5, and an indentation lateral side 28a6.

The indentation front-end side 28a3 is one end of the indentation 28 (in the +Y direction, that is, in the direction of the center of the unit storage portion 21f), and is on the same plane with the bonding front-end side 23e3 of the second connection terminal 23b (the second bonding portion 23e). The ±X direction length of the indentation front-end side 28a3 is the same as that of the bonding front-end side 23e3 of the second bonding portion 23e.

The indentation lateral sides 28a4 and 28a6 are connected to the ±X direction ends of the indentation front-end side 28a3 and are perpendicular to the indentation front-end side 28a3. The indentation lateral sides 28a4 and 28a6 are on the same plane with the bonding lateral sides 23e4 and 23e6 of the second connection terminal 23b (the second bonding portion 23e). The indentation lateral sides 28a4 and 28a6 have the same length (in the +Y directions).

The indentation rear-end side 28a5 is connected to the indentation lateral sides 28a4 and 28a6. The indentation rear-end side 28a5 includes a center portion 28a7 and lateral portions 28a8 and 28a9. The center portion 28a7 is the center portion of the indentation rear-end side 28a5 and is parallel to the indentation front-end side 28a3. The ±X direction length of the center portion 28a7 is less than the ±X direction length of the bonding rear-end side 23e5 of the second connection terminal 23b (the second bonding portion 23e). In addition, the center portion 28a7 is closer to the bonding rear-end side 23e5 of the second bonding portion 23e than the −Y direction ends of the indentation lateral sides 28a4 and 28a6. That is, the center portion 28a7 of the indentation rear-end side 28a5 protrudes in the direction opposite to the indentation front-end side 28a3.

The lateral portions 28a8 and 28a9 connect the +X direction ends of the center portion 28a7 and the −Y direction ends of the indentation lateral sides 28a4 and 28a6. Although the length of the lateral portions 28a8 and 28a9 depends on how the center portion 28a7 protrudes, the lateral portions 28a8 and 28a9 have the same length. The lateral portions 28a8 and 28a9 are connected to the center portion 28a7 at an angle less than 90°.

Cracks that occur at the corner portions C1 and C2 of the front surface 23e1 of the second bonding portion 23e in a thermal cycling test extend along arrows from the corner portions C1 and C2. However, in this case, since the length of the pressing center portion 51d1 of the pressing rear-end side 51d, which is opposite to the pressing front-end side 51b, is less than the length of the bonding rear-end side 23e5, which is another end of the second bonding portion 23e, the stress applied to the corner portions C1 and C2 is distributed in two directions (arrows F1 and F2 in FIG. 23). Thus, as in the first embodiment, the extension of the cracks in their respective directions is delayed. In addition, compared with the reference example in FIG. 20, the cracks need to extend longer to reach the bonding lateral sides 23e4 and 23e6 of the second bonding portion 23e and to fracture the second bonding portion 23e. In other words, the length of the indentation rear-end side 28a5 is greater than the length between the corner portion C1 and the corner portion C2 of the second bonding portion 23e according to the reference example in FIG. 20. Thus, even when a thermal cycling test is conducted on the semiconductor device according to the second embodiment, the extension of the cracks is delayed, and the fracture of the second connection terminal 23b (the second bonding portion 23e) is delayed. As a result, the reduction in the lifetime of the semiconductor device according to the second embodiment is prevented, and the long-term reliability is improved.

The bonding tip portion 50 (the bonding base 51) of the bonding tool 4 according to the second embodiment may have any shape, as long as the hexagonal indentation 28 illustrated in FIG. 24 is formed. That is, although the bonding base 51 has the pressing lateral sides 51a and 51c and the pressing front-end side 51b as illustrated in FIG. 23, the bonding base 51 may have a different shape such as an arc shape.

### Third Embodiment

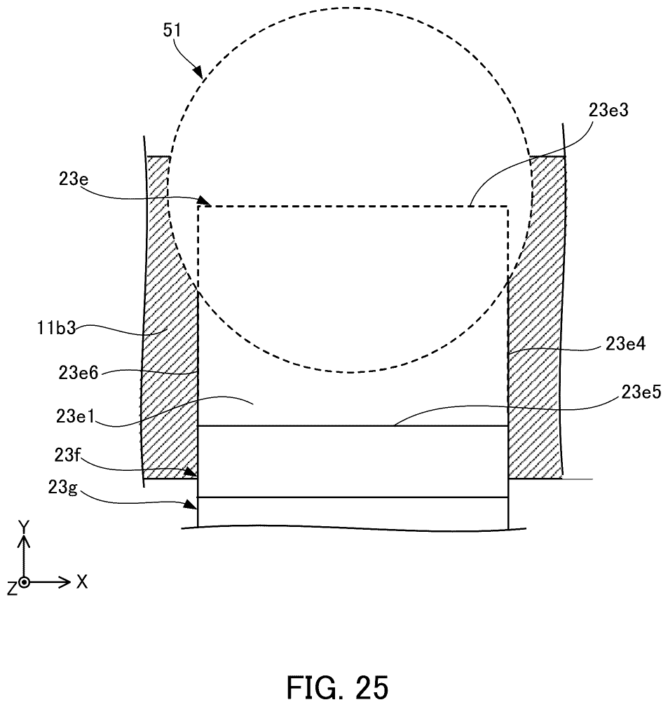

In a third embodiment, a manufacturing method of a semiconductor device 1, the manufacturing method using a bonding tip portion 50 of a bonding tool 4 having a different shape from that according to the first embodiment, will be described with reference to FIG. 25. FIG. 25 is a plan view illustrating a wiring step (at bonding) included in a manufacturing method of a semiconductor device according to a third embodiment. In FIG. 25, the location where a bonding base 51 is set is indicated by a dashed circle.

The semiconductor device according to the third embodiment may also be manufactured in accordance with the flowchart in FIG. 6. However, the planar shape of the bonding base 51 of the bonding tip portion 50 of the bonding tool 4 according to the third embodiment differs from that according to the first embodiment.

The bonding base 51 according to the third embodiment has an arc portion in its circumference in plan view. This bonding base 51 may have an oval shape (a circular shape), for example. Alternatively, the bonding base 51 may have a different shape, as long as the bonding base 51 includes an arc portion in its circumference. For example, the bonding base 51 may have a rectangular shape, and one of the four sides may have an arc shape protruding to the outside. The pressing rear-end side 51d of the bonding base 51 according to the first embodiment may have an arc shape.

The third embodiment will be described based on an example in which the bonding base 51 has a circular shape. The bonding base 51 of the bonding tool 4 has a circular shape. FIG. 25 illustrates a case in which the diameter of the bonding base 51 is greater than the length of the bonding front-end side 23e3 of the second bonding portion 23e of the second connection terminal 23b. In this case, too, a plurality of protrusions 52 are formed uniformly on the entire tip surface 51e of the bonding base 51. In addition, according to the third embodiment, too, the plurality of protrusions 52 have approximately the same height. This height is from a tip surface 51e to a pressing surface 52e of each protrusion 52. The pressing surfaces 52e of the plurality of protrusions 52 are on the same plane.

The bonding in the wiring step in step S3 in FIG. 6 is performed by using the above-described bonding tool 4. The bonding tip portion 50 of the bonding tool 4 according to the third embodiment is set on the front surface 23e1 of the second bonding portion 23e, as illustrated in FIG. 25. In this case, the bonding base 51 is set such that the arc portion of the bonding base 51 crosses the +X direction length of the second bonding portion 23e of the second connection terminal 23b.

In this state, the second bonding portion 23e of the second connection terminal 23b is pressed to the wiring plate 11b3 of the insulated circuit board 11 while being vibrated by the bonding tip portion 50 of the bonding tool 4 with a predetermined vibration frequency.

As a result, the bonding tip portion 50 of the bonding tool 4 penetrates into the front surface 23e1 of the second bonding portion 23e of the second connection terminal 23b. In this case, too, although not illustrated, burrs B occur at portions of the bonding lateral sides 23e4 and 23e6 of the second connection terminal 23b (the second bonding portion 23e), the portions having been in contact with the bonding tip portion 50 (the bonding base 51).

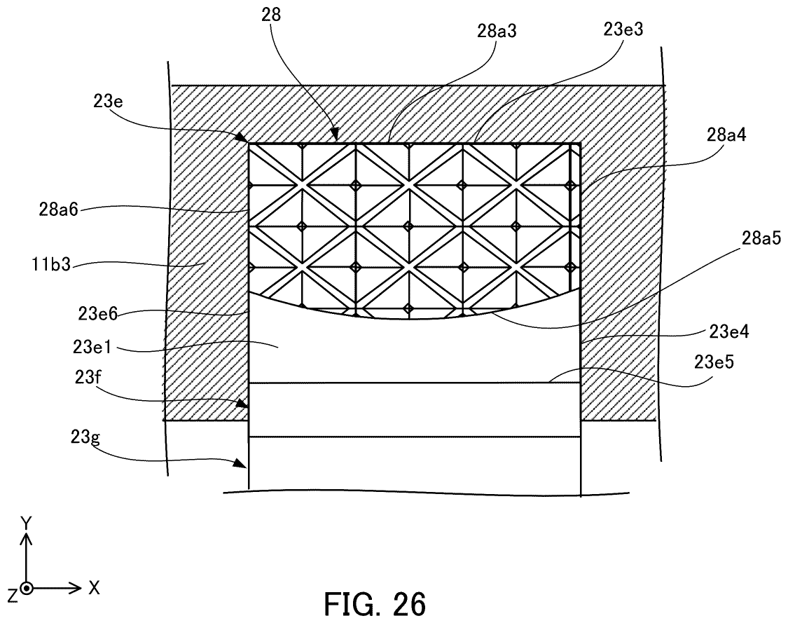

The second bonding portion 23e of the second connection terminal 23b may be bonded to the wiring plate 11b3 of the insulated circuit board 11 as described above. The state obtained after this bonding will be described with reference to FIG. 26. FIG. 26 is a plan view of a main part, illustrating the wiring step (after bonding) included in the manufacturing method of the semiconductor device according to the third embodiment. FIG. 26 illustrates the state obtained after the bonding tool 4 in FIG. 25 is removed.

After the second bonding portion 23e of the second connection terminal 23b is bonded to the wiring plate 11b3 of the insulated circuit board 11 by using the bonding tool 4, the bonding tool 4 is removed. As a result, an indentation 28 is generated on the front surface 23e1 of the second bonding portion 23e of the second connection terminal 23b as illustrated in FIG. 26.

As in the first and second embodiments, the indentation 28 is a result of the transfer of the group of concave portions and convex portions of the plurality of protrusions 52 included in the bonding tip portion 50 of the bonding tool 4 to the front surface 23e1 of the second bonding portion 23e of the second connection terminal 23b. The second bonding portion 23e has an indentation portion 23e7 to which the indentation 28 has been transferred. Although not illustrated, the indentation portion 23e7 is a concave portion with respect to the front surface 23e1 of the second bonding portion 23e of the second connection terminal 23b, and is located below the front surface 23e1, as described above. In plan view, the indentation 28 includes an indentation front-end side 28a3, an indentation lateral side 28a4, an indentation rear-end side 28a5, and an indentation lateral side 28a6.

The indentation front-end side 28a3 is one end of the indentation 28 (in the +Y direction, that is, in the direction of the center of the unit storage portion 21f), and is on the same plane with the bonding front-end side 23e3 of the second connection terminal 23b (the second bonding portion 23e). The ±X direction length of the indentation front-end side 28a3 is the same as the ±X direction length of the bonding front-end side 23e3 of the second bonding portion 23e.

The indentation lateral sides 28a4 and 28a6 are connected to the ±X direction ends of the indentation front-end side 28a3 and are perpendicular to the indentation front-end side 28a3. The indentation lateral side 28a4 is on the same plane with the bonding lateral side 23e4 of the second bonding portion 23e of the second connection terminal 23b. The indentation lateral side 28a6 is on the same plane with the bonding lateral side 23e6 of the second bonding portion 23e of the second connection terminal 23b. The indentation lateral sides 28a4 and 28a6 have the same length (in the +Y directions).

The indentation rear-end side 28a5 is connected to the indentation lateral sides 28a4 and 28a6. The center of the indentation rear-end side 28a5 protrudes in the direction opposite to the indentation front-end side 28a3. That is, the indentation rear-end side 28a5 has an arc shape.

The front surface 23e1 of the second bonding portion 23e of the second connection terminal 23b is pressed by the above-described bonding tip portion 50 of the bonding tool 4 according to the third embodiment. In this case, the bonding tip portion 50 (the bonding base 51) of the bonding tool 4 has an arc portion in its circumference. As a result, the indentation rear-end side 28a5 of the indentation 28 of the front surface 23e1 of the second bonding portion 23e also has an arc shape, and occurrence of cracks is reduced more than that according to the first and second embodiments.

Even if a crack occurs in any portion of the indentation rear-end side 28a5 of the indentation 28 of the front surface 23e1 of the second bonding portion 23e, since the indentation rear-end side 28a5 of the indentation 28 has an arc shape, the stress applied to the crack is distributed in two directions along the arc. Thus, as in the first and second embodiments, the extension of the crack in these directions is delayed. Therefore, even when a thermal cycling test is conducted on the semiconductor device according to the third embodiment, the extension of the crack is delayed, and the fracture of the second connection terminal 23b (the second bonding portion 23e) is consequently delayed. As a result, the reduction in the lifetime of the semiconductor device according to the third embodiment is prevented, and the long-term reliability is improved.

The technique described herein prevents the reduction in the lifetime of the bonding to electrically conductive portions and prevents the deterioration of the long-term reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an electrically conductive portion; and
a terminal,
wherein the terminal includes a bonding portion that is of a flat plate shape,
wherein the bonding portion has:
a rear surface bonded to the electrically conductive portion, and
a front surface having an indentation formed thereon,
wherein the front surface has two opposite sides that are respectively a bonding front-end side and a bonding rear-end side,
wherein the indentation has two opposite sides that are respectively an indentation front-end side and an indentation rear-end side,
wherein the indentation front-end side is flush with the bonding front-end side, and
wherein a length of the indentation rear-end side is shorter than a length of the bonding rear-end side.

2. The semiconductor device according to claim 1, wherein the indentation further has a pair of indentation lateral sides that each connect the indentation front-end side and the indentation rear-end side.

3. The semiconductor device according to claim 2, wherein a length of the indentation front-end side of the indentation is shorter than a length of the bonding front-end side of the front surface.

4. The semiconductor device according to claim 3, wherein
the indentation has a rectangular shape in a plan view of the semiconductor device, and
the indentation front-end side and the indentation rear-end side have a same length.

5. The semiconductor device according to claim 4,
wherein the front surface further includes a pair of bonding lateral sides that are each perpendicular to the bonding front-end side and the bonding rear-end side, and
wherein the pair of bonding lateral sides are located on a more outer side of the front surface than the pair of indentation lateral sides of the indentation.

6. The semiconductor device according to claim 5,
wherein a distance between each of the indentation lateral sides of the indentation and one of the pair of the bonding lateral sides of the front surface closer thereto is 1 mm or greater in the plan view.

7. The semiconductor device according to claim 5, wherein a sum of the length of the indentation rear-end side and lengths of the pair of indentation lateral sides of the indentation is greater than the length of the bonding front-end side of the front surface.

8. The semiconductor device according to claim 1, wherein the indentation rear-end side of the indentation protrudes in a direction opposite to the indentation front-end side.

9. The semiconductor device according to claim 8,
wherein the indentation rear-end side of the indentation includes a center portion and a pair of connection portions respectively on two sides of the center portion,
wherein a length of the center portion of the indentation rear-end side is shorter than the length of the bonding rear-end side of the front surface, and
wherein the center portion is farther from the indentation front-end side than is each of the connection portions.

10. The semiconductor device according to claim 9, wherein the center portion of the indentation rear-end side is parallel to the bonding rear-end side.

11. The semiconductor device according to claim 1, wherein the indentation is formed by a group of concave portions and convex portions.

12. The semiconductor device according to claim 11, wherein top portions of the convex portions included in the group are on approximately a same plane.

13. The semiconductor device according to claim 1,
wherein the terminal further includes
a linkage portion that is integrally connected to the bonding rear-end side at the front surface of the bonding portion and that rises upward from the front surface, and
a wiring portion that is connected to an end of the linkage portion and that extends to a more outer side of the bonding portion than the electrically conductive portion in a plan view of the semiconductor device, and
wherein the semiconductor device further includes a case that stores the electrically conductive portion and that fixes the wiring portion of the terminal.

14. A semiconductor device, comprising:
an electrically conductive portion; and
a terminal,
wherein the terminal includes a bonding portion that is of a flat plate shape,
the bonding portion has:
a rear surface bonded to the electrically conductive portion, and
a front surface having an indentation formed thereon,
wherein the front surface has two opposite sides that are respectively a bonding front-end side and a bonding rear-end side,
wherein the indentation has two opposite sides that are respectively an indentation front-end side and an indentation rear-end side,
wherein the indentation front-end side is flush with the bonding front-end side, and
wherein the indentation rear-end side has an arc shape protruding in a direction opposite to the indentation front-end side.
